(19) United States
(12) Patent Application Publication
(10) Pub. No.: US 2026/0310197 A1
(43) Pub. Date: Oct. 8, 2026

(54) SYSTEMS AND METHODS FOR INTEGRATING ARTIFICIAL INTELLIGENCE IN A COMMON OPERATING PICTURE

(71) Applicant: Anduril Industries, Inc., Costa Mesa, CA (US)

(72) Inventors: Achinthya Soordelu, Irvine, CA (US); Jackson Riley Grilliot Kearl, Orange, CA (US)

(21) Appl. No.: 19/397,676

(22) Filed: Nov. 21, 2025

Related U.S. Application Data
(60) Provisional application No. 63/783,768, filed on Apr. 4, 2025.

(51) Int. Cl. G05D 1/229; G06F 3/04842; G06N 20/00

(52) U.S. Cl. CPC G05D 1/229; G06F 3/04842; G06N 20/00

(57) ABSTRACT

A system may access data associated with objects, cause a graphical user interface to display the objects and information associated with potential actions between objects, receive user input associated with potential actions, generate a prompt for an artificial intelligence (AI) model, including potential actions, accessed data, and instructions to generate an overview. A system may receive and display a response from an AI model with an overview potential actions. A system may generate a prompt for an AI model, including a particular potential action accessed data and instructions to generate a summary. A system may receive and display information associated with a response with a summary of a potential action from an AI model with summary of the particular potential action.

### INCORPORATION BY REFERENCE TO ANY PRIORITY APPLICATIONS

This application claims benefit of U.S. Provisional Patent Application No. 63/783,768, filed Apr. 4, 2025, and titled “SYSTEMS AND METHODS FOR INTEGRATING ARTIFICIAL INTELLIGENCE IN A COMMON OPERATING PICTURE.” The entire disclosure of each of the above items is hereby made part of this specification as if set forth fully herein and incorporated by reference for all purposes, for all that it contains.

Any and all applications for which a foreign or domestic priority claim is identified in the Application Data Sheet as filed with the present application are hereby incorporated by reference under 37 CFR 1.57.

### TECHNICAL FIELD

Implementations of the present disclosure relate generally to systems and methods for integrating artificial intelligence in a common operating picture or environment. Implementations of the present disclosure relate to devices, systems, and methods for evaluating logic used to generate the common operating picture and/or for digesting information related to the common operating picture.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Computer-implemented systems can track objects within a physical or virtual operating environment. Such systems can generally display information associated with the tracking.

### BRIEF DESCRIPTION OF THE DRAWINGS

The following drawings and the associated descriptions are provided to illustrate implementations of the present disclosure and do not limit the scope of the claims. Aspects and many of the attendant advantages of this disclosure will become more readily appreciated as the same become better understood by reference to the following detailed description, when taken in conjunction with the accompanying drawings.

FIG. 1 illustrates a block diagram of an example operating environment in which one or more aspects of the present disclosure may operate, according to various implementations of the present disclosure.

FIG. 2 illustrates a block diagram of a further example operational environment of the system, according to various implementations of the present disclosure.

FIG. 3 is a block diagram illustrating operation of an evaluator explainer module, according to various implementations of the present disclosure.

FIG. 4 illustrates an example process of generating overviews of potential actions between objects, according to various implementations of the present disclosure.

FIG. 5 illustrates an example process of generating summaries of particular objects, according to various implementations of the present disclosure.

FIG. 6 illustrates an example process of generating follow up responses from an artificial intelligence model based on potential actions between objects, according to various implementations of the present disclosure.

FIG. 7 is a block diagram illustrating operation of a rules and procedures module, according to various implementations of the present disclosure.

FIG. 8 illustrates an example process of generating indications that potential actions comply with a set of rules and procedures, according to various implementations of the present disclosure.

FIG. 9 illustrates an example process of receiving authorization for a potential action, according to various implementations of the present disclosure.

FIG. 10 illustrates an example process of receiving verifications and corrections by a rules and procedures module, according to various implementations of the present disclosure.

FIG. 11 is an example table of object types and associated properties and rules, according to various implementations of the present disclosure.

FIG. 12 illustrates an example table linking object types, according to various implementations of the present disclosure.

FIGS. 13-16 illustrate example graphical user interfaces, according to various implementations of the present disclosure.

FIG. 17 illustrates a block diagram of an example computing device, according to various implementations of the present disclosure.

### DETAILED DESCRIPTION

Although certain implementations and examples are disclosed below, inventive subject matter extends beyond the specifically disclosed implementations to other alternative implementations and/or uses and to modifications and equivalents thereof. Thus, the scope of the claims appended hereto is not limited by any of the particular implementations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain implementations; however, the order of description should not be construed to imply that these operations are order dependent. Additionally, the structures, systems, and/or devices described herein may be embodied as integrated components or as separate components. For purposes of comparing various implementations, certain aspects and advantages of these implementations are described. Not necessarily all such aspects or advantages are achieved by any particular implementation. Thus, for example, various implementations may be carried out in a manner that achieves or optimizes one advantage or group of advantages as taught herein without necessarily achieving other aspects or advantages as may also be taught or suggested herein.

### Overview

Aspects of this disclosure relate to tracking and generating potential actions between objects and displaying the same. As used herein, an object can refer to a real world or simulated person, group of people, entity, building, vehicle, equipment (e.g., sensing systems, weapons, and/or other suitable equipment) and/or any other thing or system that can be tracked, act in relation to another object, and/or be acted upon. Two objects may have an action take place between them (which can be referred to generally herein as an “action”). For example, a delivery truck may deliver a parcel to a facility, a firetruck may travel to a destination where a building is on fire, or two radio devices may establish a datalink, to list a few non-limiting examples. An action between two objects may be performed based on an associated task. For example, a task may be to pick up a passenger in a vehicle and an associated action may be to travel to the passenger. In many situations, it may be beneficial to determine multiple options for performing a task. For example, if a building (an object) is on fire, it may be desirable to determine which of multiple firetrucks (other objects) should be deployed (action) to respond to the fire (task to be performed). In this example, many different factors may influence which firetruck is chosen (e.g., a proximity to the building, a tanker capacity, whether the firetruck is deployed elsewhere, and/or the like).

Disclosed herein are systems, methods, and devices (generally referred to as the “system”) that may track various objects and determine options for accomplishing a given task between two or more objects (e.g., determining one or more potential actions between the two or more objects). For instance, implementations of this disclosure relate to tracking and/or simulating objects, such as vehicles, in a geographic area and determining options for which object is to take an action toward a target object (e.g., follow, monitor, surveil, track and/or deploy munitions to damage or destroy a target vehicle). However, the disclosure is not limited to such implementations. Often, determining options of potential actions involves processing large amounts of information quickly. For example, in the implementation described above, the system may track and process vehicle position, heading, speed, altitude, payload details, and/or other suitable vehicle properties for many (e.g., 10, 20, 50, 100, or more) different vehicles in a geographic area to determine suitable options for performing the task.

The disclosed system can include an evaluator engine that can receive the tracked information and a task to be performed and determine options of potential actions between objects to accomplish the task. For example, in the implementation described above, if the task is to damage or destroy a target vehicle, the evaluator engine can determine which of the vehicles can take damage or destroy the target object. This determination can include, but is not limited to, determining munitions available to each vehicle, determining capabilities of the munitions, determining if each vehicle is in range, given available munitions, and/or other suitable considerations. The logic used by the evaluator engine to make the determinations of the options of potential actions can be referred to the evaluator engine logic. In determining the available options of potential actions, the evaluator engine may also determine that one or more objects, while feasible given the data, cannot be performed. For example, accomplishing a task may require a vehicle to travel through a restricted area, making the vehicle unsuitable or unavailable for the task. This determination can include determining whether one or more test conditions or rules are met. The evaluator engine logic can also include the logic used by the evaluator engine to make the determinations that objects cannot perform the task.

The options for accomplishing a task may be displayed to a user (e.g., via a graphical user interface) where the user can select options, and in some instances, cause the selected option to be executed. For example, a user may select an option of a fire engine to be deployed to a fire alerting the relevant station to deploy that fire engine. However, a user selecting which option to execute may wish to have more information about the various options. For example, a user may wish to know why particular options were determined, why a particular option has been flagged as failing to pass a test, a summary of available options, detailed information regarding a particular option, and/or other useful information for understanding the presented options. However, as described above, the evaluator engine may have processed a large amount of information, which may not be practical for a user to review. Further, a user may not have the specific knowledge to interpret the information used by the evaluator engine. Furthermore, the information may change rapidly, rendering the options inapplicable if too much time passes and/or may otherwise be impractical or undesirable for a user to review unaltered. To address these, and other potential problems, the disclosed system can include an evaluator explainer. As described in more detail below, the evaluator explainer can provide a user with information associated with the generation of options performed by an evaluation engine. For example, in some instances, the evaluator explainer can provide a summary of the determined options and relevant aspects of the determination.

### Example Aspects of an Evaluator Explainer

According to various implementations, an evaluator explainer may include and/or interface with one or more artificial intelligence (“AI”) models, such as language models (“LMs”), large language models (“LLMs”), Machine Learning (“ML”) models, and/or other AI models. AI models can be useful for data processing, including receiving natural language prompts and providing responses based on data on which the AI model is trained. While other types of AI models may be used in various implementations, for convenience, reference will be made to the use of LLMs in the present disclosure. The evaluator explainer may include information used to generate options, logic used by the evaluator engine, and, in some instance, input from a user in a prompt to an LLM. In various implementations, the evaluation explainer may generate a prompt for the LLM by populating a template prompt with the information used to generate options, logic used by the evaluator engine, and input from the user. The template prompt may also include instructions (e.g., static descriptions or instructions) to the LLM on what to do with the information. An example LLM prompt is illustrated below:
{{Role/Assignment Preamble}}
Using the following background context:
   {{Table_1}}
   {{Table_2}}
   {{Documentation}}
A request has been made to execute the following task:
   {{Task Data}}
Evaluate the recommended actions provided below in the context of the above tables and provide a general summary of all the possible options, followed by a more detailed analysis of each individual option, your response should be in standard JSON format:
   {{List of Recommended Options}}
   {{Evaluator Engine Logic}}
   {{Languages}}
{{Formatting Postamble}}

In the prompt above, information displayed between double brackets (between “{{” and “}}”) can represent larger portions of the template prompt and/or information imported into the template prompt to generate the prompt. The “{{Role/Assignment Preamble}}” may include a textual description of the role the LLM is to take (e.g., “You are a helpful assistant tasked with analyzing vehicle data for a geographic area. You always use the following in your analysis.”). The “{{Table_1}}”, “{{Table_2}}”, and “{{Documentation}}” can provide information and context an evaluator engine used to generate the list of recommended options. This information can include, but is not limited to, tables of defining object types, object properties, links between objects and/or object types, rules or constraints for objects, and/or other information used to generate the recommended options. The “{{Task Data}}” can represent information in the prompt associated with the task the evaluator engine generated the options based on (e.g., “travel to object A and retrieve a package”). The “{{List of Recommended Options}}” can represent one or more options between two (or more) objects that the evaluator engine generated that can perform the task identified in “{{Task Data}}”. The “{{Evaluator Engine Logic}}” can represent the logic the evaluator engine used to determine the generated options (e.g., one or more links between objects, properties considered, relevant data to the decisions, and/or other information). The “{{Languages}}” can represent information given to the LLM about the language information is provided in and/or should be generated in (e.g., “Your response should be determined and given in the following languages: English and Japanese”). The “{{Formatting Postamble}}” can include additional information for formatting the response (e.g., instructions giving user preferences and how the user preferences are to be preserved, instructions to avoid speculation, instructions regarding the level of background knowledge to use for the response, and/or any other suitable instructions for generating an applicable response).

As stated above, some portions of the prompt can be dynamic. For example, “{{Table_1}}” may be populated into the prompt based on real-time updates to a table of data at the time the prompt was generated. Some information provided to the LLM may be temporality retained by the LLM and/or saved in the system and used in follow on prompts generated and sent to the LLM (e.g., along with the user input questions described below). For example, current states of the objects (e.g., position, velocity, bearing, and/or other suitable indication of object state), static contextual information (e.g., tables of data, relevant rules, and/or other relevant static contextual information), and/or information used for user display preferences (e.g., embedded html tags) can be provided to the LLM and maintained by the LLM and/or system throughout the processes described below.

After the generated prompt is provided to the LLM, the evaluator explainer may receive and display a result from the LLM to a user. In various implementations, the results are displayed on a graphical user interface along with the task to be performed, the potential options for accomplishing a task, the relevant objects (e.g., all the object in a particular geographic area considered by the evaluator engine), and/or other information. In various implementations, rather than displaying the result on the graphical user interface, an indication of the result is displayed on the graphical user interface (e.g., an indication that a summary has been generated). The results can then be displayed based on a user input interacting with the indication (e.g., a mouse click on the indication or hovering a cursor over the indication).

In various implementations, multiple interactions between the system and an LLM may be triggered by a single user input. In an illustrative example, a graphical user interface may display objects and potential actions between the objects. A user may select an option on the graphical user interface to initiate the evaluator explainer. This selection may trigger the system to generate a prompt for the LLM by using the potential actions, the evaluator engine logic used to determine the potential actions, the relevant information used by the evaluator engine, and instructions to generate an overview of the potential actions (e.g., by using a template prompt described above). The system can then provide the prompt to an LLM and receive a response from the LLM with the generated overview of the potential actions. The system can display the overview to a user on the graphical user interface.

In an illustrative example, without further user input, the system can generate one or more subsequent prompts for generating summaries for each of the potential options. The prompts can each include a particular potential action to summarize, associated evaluator engine logic and relevant information used by the evaluator engine to determine the particular potential action, and instructions to generate a summary of the particular potential action. The system can provide the subsequent prompts to the LLM, receive response from the LLM, and display indications of the summaries of the options of potential actions on the graphical user interface. In various implementations, rather than providing separate prompts, the system can generate a prompt that includes the above described information and instructions to generate and overview of the options and a summary of each individual option in a single prompt.

In some instances, the user may desire further information regarding the generated options. The evaluator explainer may generate, automatically or in response to a user input, and display a field for the user to input questions associated with the options. The user input can be in plain language (e.g., a plain English question). For example, the user input can be the text string, “Why did option 1 fail a test?”. The user input can be included in a generated prompt in a similar manner as described above (e.g., by using a template) along with the needed contextual information (e.g., the information used to generate options and logic used by the evaluator engine) and provided to the LLM. In various implementations, the LLM or system may retain contextual information, which may simplify the prompt. The evaluator explainer may receive an LLM response and display the response on the graphical user interface. The evaluator engine may receive additional user input and repeat the process described above to generate LLM prompts and receive and display LLM responses. In various implementations, the user input and the LLM responses may be displayed together on the graphical user interface.

The various LLM responses may include answers in more than one language. In various implementations, the LLM responses of different languages may be determined separately, meaning that the LLM can generate the response in a first language and a response in a second language, using the same information, rather than generating a response in the first language and translating the response to the second language. In various implementations, the languages may be translated.

For illustrative purposes, a non-limiting example implementation of the system will be described. As described above, one implementation of the system involves tracking vehicles in a geographic region. In this implementation, the system may track the vehicles by using positional data from the vehicles themselves, from sensing systems (e.g., sensor towers), sensor data from other vehicles (such are surveillance vehicles), from simulated data, from other sources, or from any combination thereof. The system may label some of the vehicles as enemy vehicles. The system can select, based on user input or otherwise, a vehicle as a target vehicle. The evaluator engine can determine, using the tracked vehicle data and weapon information (e.g., data defining munition attributes and salvo information of which object has access to specific munitions) to determine which of the objects can be used to attack the target vehicle.

In this example implementation, options of objects that can be used can be presented to a user on a graphical user interface. The user may then decide which of the options to deploy. However, the user may wish to have additional information to contextualize the decision. For example, a user may wish to have a summary of the options presented, to know why a particular vehicle was not presented as an option, to know why one or more of the options are flagged as failing a test, and/or may have other questions that may be important in the decision process. The user may activate the evaluation explainer to provide the additional information.

In the example implementation, a user may select to activate the evaluation explainer. The evaluation explainer may then generate an overview of all the options and a summary of each option provided by the evaluation engine. To do so, the evaluation explainer may provide the options, the evaluator engine logic, the tracked vehicle data, and/or weapon information in one or more prompts (e.g., by using the techniques described above) to one or more LLMs. The evaluation explainer may receive the overview and summaries of the options and display them on the graphical user interface for the user to review.

In some instances, the user may still desire further contextual information. For example, a user may want to know why a vehicle within range of the target vehicle is not included as an option and/or the user may want to know why a particular option failed a test. The user may input a question into the graphic user interface, which is then provided in a prompt to an LLM with other information (e.g., the options, the evaluator engine logic, the tracked vehicle data, and/or weapon information, and/or the previous LLM response(s)). For example, the user may input the text string, “Why did option 3 fail a test?” which can be included in the prompt with the other information. The evaluation explainer may receive the LLM response and display it to the user. For instance, in the example user input above, the LLM response may include text similar to “Option 3 failed a track quality test. The tracking data of Object 5 did not meet the threshold requirement of the track quality test.”, which may be displayed on the graphical user interface with the associated user input. The evaluator explainer may allow the user to continue to enter user input (e.g., as questions) and display the results. In the example implementation, once the user is satisfied, the user may enter user input on the graphical user interface selecting one or more of the options for attacking the target.

### Example Aspects of a Rules and Procedures Module

As described above, system can (e.g., by using an evaluator engine) receive tracked information and a task to be performed and determine options of potential actions between objects to accomplish the task. In some instances, documentation (collectively referred to herein as “rules and procedures”) may dictate whether each of the determined potential actions are permitted to be performed, influence how one or more of the potential actions should be performed, and/or otherwise dictate or influence the performance of potential actions. As a potential effect of the rules and procedures, actions (e.g., potential actions between objects) that are theoretically possible (e.g., the actions could be performed given object capabilities and current conditions) may not be viable or permitted because the action is counter to the rules and procedures.

The rules and procedures can include large amounts of information (e.g., 10s, 100s, 1000s, or more pages or documents of documentation). Further, in some instances, the rules and procedures may be dynamic and ever evolving (e.g., the rules and procedures may be continually updated). Furthermore, some of the rules and procedures may have a relatively high level of specificity and/or have relatively narrow applicability. For example, some of the rules and procedures may be specific to an object type, an object, a property of an object or object type, an operating environment, and/or specific to other information used to determine and/or execute an action. Accordingly, it can be difficult to determine when any of the rules and procedures apply to a given action, which of the rules and procedures apply to a given action, whether any of the rules and procedures prevent or change the given action, and/or whether the rules and procedures influence the given action in other ways.

According to aspects of the disclosure, the system can include a rules and procedures module that can address the above mentioned, and other technical problems, that can arise from the rules and procedures. According to various implementations, the rules and procedures module can determine applicable portions of a set of rules and procedures (referred to herein as “logical blocks” of the set of rules and procedures) and determine whether potential actions between objects comply with the rules and procedures. The rules and procedures model can include and/or interface with AI models, such as LLMs, which can perform some of the operations of the rules and procedures module described herein.

In various implementations, the rules and procedures module can access information indicating potential actions between objects. The information could be generated or determined by the system (e.g., by using an evaluation engine), entered by a user (e.g., by one or more user inputs) and/or otherwise generated or determined. The rules and procedures module can use the accessed information and a set of rules and procedures to determine whether potential actions comply with the set of rules and procedures. In various implementations, the rules and procedures module can automatically begin the determination. In other implementations, the rules and procedures module can begin the determination based on user input (e.g., a user selecting a potential action on a graphical user interface or a user entering a potential action for the system to check on the graphical user interface). As described above, the set of rules and procedures can include a relatively large amount of information. As such, the set of rules and procedures may be too large to be referenced in some situations. For example, the set of rules and procedures may be too large to provide to an LLM in a prompt (e.g., the set of rules and procedures exceeds a character limit and/or would take an impractically long time to process).

The rules and procedures module can determine logical blocks from a set of rules and procedures related to the potential actions and/or the objects. In various implementations, the rules and procedures module can determine the logical blocks by using a similarity search on the set of rules and procedures. The similarity search can include searching the set of rules and procedures for words or phrases associated with the potential actions and/or the objects. The logical blocks can be documents of set of rules and procedures where the words or phrases occur, pages of the set rules and procedures where the words or phrases occur, sections of the set rules and procedures where the words or phrases occur, sentences of the set rules and procedures where the words or phrases occur, and/or other partitions of the set of rules and procedures associated with the words or phrases. In various implementations, the rules and procedures module can determine the logical blocks using other techniques. For example, using metadata to associate the potential actions and/or objects to portions of the set of rules and procedures.

In an example, one potential action could be for a vehicle (e.g., an object) to drive (e.g., potential action) to a building (e.g., a second object). In this example the similarity search can include: a search of the vehicle make and model, a search on the location/orientation of the vehicle (e.g., as indicated in the accessed information), a search of drive (or other synonymous terms or phrases), a search on the location of the building and/or other words or phrases associated with the vehicle, driving, or building. The result of this example search could include logical blocks such as: operations manuals of the vehicle, documentation of a projected route (e.g., road types, speed limits, and/or the like), and/or documentation associated with the building, to list a few examples.

The rules and procedures module can use the determined logical blocks of the set of rules and procedures in a prompt to an LLM. In various implementations, the rules and procedures module can generate a prompt for an LLM that includes the one or more potential actions, the accessed information, the determined logical blocks from the set of rules and procedures, and instructions for the LLM to generate indications of whether each of the potential actions complies with the provided rules and procedures. In various implementations, the prompt can include other information and/or omit some of the above-mentioned information. The rules and procedures module can provide the prompt to the LLM. The rules and procedures module can generate the prompt in a similar manner as the evaluator explainer (e.g., using a template prompt with static and dynamic portions).

The rules and procedures module can receive a response from the LLM with the indications of whether each of the potential actions complies with the set of rules and procedures. The rules and procedures module can cause a graphical user interface to display each of the potential actions along with an associated indication of whether the potential action complies with the set of rules and procedures.

In some instances, a user may wish to perform a potential action indicated by the rules and procedures module as not complying the set of rules and procedures and/or may otherwise wish to receive authorization for the potential action. According to various implementations, a user may select a particular potential action associated with an indication that the particular action does not comply with the set of rules and procedures. The rules and procedures module can receive the user input and send and/or cause the particular potential action to be displayed to a user with authority to authorize the potential action. In various implementations, the particular action is displayed to the user with authority to authorize the potential action on a different graphical user interface than was used by the user wishing to perform the potential action. For example, the user with authority to authorize the potential action may have access to a graphical user interface that includes the capability to provide authority to perform actions (e.g., via one or more buttons, fields, and/or the like, of the graphical user interface). The rules and procedures module can receive an input from the separate graphical user interface with an authorization from the user with authority permitting (or authorizing) the particular action to be performed. The rules and procedures module can generate an alert and display (e.g., on a graphical user interface) the alert to the user wishing to perform the potential action that the potential action has been authorized.

According to various implementations, when the authorization is received the rules and procedures module (or other components of the system) may perform one or more operations. For instance, the rules and procedures module (or other components of the system) may redetermine and/or update the potential actions, the objects, logical blocks of the set of rules and procedures, to reflect the authorization (and any other changes that may have occurred in the interim). As such, some of the potential actions determined before may be removed and/or some additional potential actions and associated objects may be added based on the authorization and/or other changes that occurred. Similarly, the logical blocks may be different based on the change in the potential actions, objects, and/or based on the authorization.

The rules and procedures module can generate a second prompt for an LLM that includes the potential actions, the accessed information, and the logical blocks from the set of rules and procedures, some, or all, of which may have been updated. The prompt can also include the authorization and instructions, including instructions to generate updated indications of whether each of the potential actions complies with the set of rules and procedures. The system can generate the prompt, receive a response with the indications and display the indications in a manner similar as is described above with respect to the first interaction with the LLM.

In various implementations, some, or all of the information used and generated by the rules and procedures module may be tracked and/or recorded in a log. For example, the rules and procedures module may track the accessed information, the potential actions, the logical blocks, the generated prompts, the responses received from an LLM, requests for authorization of potential actions, authorizations, and/or other information used or generated by the rules and procedures module or users may be tracked and/or recorded in a log. The log, or a portion of the log, can be presented to a user (e.g., a human in the loop) via another graphical user interface (e.g., a third graphical user interface). The rules and procedures module can receive input from the user verifying or correcting one or more items of the log. For example, the user may verify or correct the determined logical blocks, the indications whether a potential action complies with the set of rules and procedures, the set of rules and procedures, authorizations to perform particular potential actions, and/or other information in the log. The rules and procedures module can record the verifications and corrections. The rules and procedures module then reperform any of the above-described operations in light of the recorded verifications and corrections. For example, the rules and procedures module may redetermine the potential actions, the objects, and the logical blocks and regenerate a prompt to the LLM based on the recorded verifications and corrections.

For illustrative purposes, an example implementation of the rules and procedures module is described below. In a battlefield context, many actions are regulated. Some of the regulations can include tactics, techniques, and procedures (“TTPs”) and rules of engagement (“RoEs”), and other regulations, which can collectively be considered a set of rules and procedures. Some of the set of rules and procedures can be narrowly defined (e.g., operating rules for a specific vessel in a given set of circumstances), broadly encompassing (general rules of international or other law), or somewhere in between. Accordingly, the set of relevant rules and procedures for any given operating environment can have a relatively large amount of documentation to consider. Accordingly, in the example implementation, the rules and procedures module can use a set of rules and procedures and determine/indicate whether potential actions within the battlefield comply with the rules and procedures. For example, the rules and procedures module may determine whether one vehicle attacking another vehicle with a specified munition complies with the set of rules and procedures.

To do so, the rules and procedures module can determine logical blocks of the set of rules and procedures, generate prompts for an LLM, receive responses with indications that potential actions comply (or do not comply) with the set of rules and procedures, and display the indications by using the above described techniques. Further, the rules and procedures module may allow a user to escalate a potential action up the line of command by selecting a particular potential action (or indication thereof). The selected particular potential action can be sent and/or displayed to a user with authority to authorize the action (e.g., a commanding officer). The system may receive the authorization, generate alerts, update potential action, update logical blocks, regenerate prompts, and/or perform other operations based on the authorization. The results can include, for example, that the particular potential action can be performed, that other potential actions are generated by the system, that other potential actions that previously did not comply with the set of rules and procedures are determined to comply with the set of rules and procedures (e.g., the other potential actions may have been constrained by the same logical blocks as the authorized potential action), and/or other results described herein.

As described above, information associated with the rules and procedures module may be tracked and/or recorded in a log and presented to a user. The user may then verify or correct portions of the log. In the battlefield example, the user may be a Judge Advocate General (“JAG”) or other user with the required knowledge and/or authority to provide the corrections and verifications. As described above, the corrections and verifications can be recorded and the rules and procedures module may update various aspects in the manner described above based on those aspects.

### Example Aspects of Graphical User Interfaces

As described above, one or more graphical user interfaces can be used by the system to display information, such as the overviews and summaries of options of potential actions associated with a task. Further, the one or more graphical user interfaces can be used to received user inputs, such as a user input to initialize an evaluator explainer, a user input with a question regarding the options of potential actions, and/or other user input.

The information on the graphical user interface may be displayed based on user preference. For example, a user may set a preference in the system that all distances be displayed in metric units. According to various implementations, the system may utilize marking or tagging scheme to preserve the user preference. In various implementations, the instructions to the LLM included in each of the prompts can have instructions for marking or tagging information the LLM generates such that when the system receives and displays that information, the user preferences are maintained. In a nonlimiting example, the system may include instructions for the LLM to output in JavaScript Object Notation (“JSON”) format. Relevant portions (e.g., portions that can be displayed differently based on user preference) of the JSON format can be associated with HyperText Markup Language (“HTML”) tags in marked down strings. When parsing the marked down strings, the system can identify the HTML tags and display the information according to the user preference.

As mentioned above, the graphical user interface can display information in multiple languages. For example, overviews, summaries, and responses to questions the system receives from the LLM can be displayed in multiple languages simultaneously. In various implementations, the languages are not directly translated from each other. Rather, the instructions to the LLM can include instructions to generate answers in each of the desired languages. In some situations, this can provide more accurate representations of the information in each language, as the answers are generated from the base input, with the context provided therefrom when compared to a direct translation from one language (e.g., receiving an output in English and translating the English output into another language).

As described above, various graphical user interfaces can be used to display information associated with the rules and procedures module. For example, to display potential actions between objects, indications whether the potential actions comply with a set of rules and regulations, display potential actions to a user with authority to authorize the potential actions (on a second graphical user interface), display alerts a potential actions have been authorized, display logs to another user (on a third graphical user interface), and/or display other information described herein. These various graphical user interfaces can be used to receive user input in association with the rules and procedures module. For example, the various graphical user interfaces can receive: user input selecting a potential action and/or object, user input describing a potential action, user input requesting a particular potential action be authorized, user input authorizing a particular action, user input correcting or verifying a log, and/or other user input described herein.

### Further Example Information Related to Various Implementations

To facilitate an understanding of the systems and methods discussed herein, several terms are described below and herein. These terms, as well as other terms used herein, should be construed to include the provided descriptions, the ordinary and customary meanings of the terms, and/or any other implied meaning for the respective terms, wherein such construction is consistent with context of the term. Thus, the descriptions below and herein do not limit the meaning of these terms, but only provide example descriptions.

The term “model,” as used in the present disclosure, can include any computer-based models of any type and of any level of complexity, such as any type of sequential, functional, or concurrent model. Models can further include various types of computational models, such as, for example, artificial neural networks (“NN”), language models (e.g., large language models (“LLMs”)), artificial intelligence (“AI”) models, machine learning (“ML”) models, multimodal models (e.g., models or combinations of models that can accept inputs of multiple modalities, such as images and text), and/or the like. A “nondeterministic model” as used in the present disclosure, is any model in which the output of the model is not determined solely based on an input to the model. Examples of nondeterministic models include language models such as LLMs, ML models, and the like. In general, the term “AI model,” as used herein, may refer to any ML model, NN, language model, and/or the like.

A Language Model is any algorithm, rule, model, and/or other programmatic instructions that can predict the probability of a sequence of words. A language model may, given a starting text string (e.g., one or more words), predict the next word in the sequence. A language model may calculate the probability of different word combinations based on the patterns learned during training (based on a set of text data from books, articles, websites, audio files, and/or the like). A language model may generate many combinations of one or more next words (and/or sentences) that are coherent and contextually relevant. Thus, a language model can be an advanced artificial intelligence algorithm that has been trained to understand, generate, and manipulate language. A language model can be useful for natural language processing, including receiving natural language prompts and providing natural language responses based on the text on which the model is trained. A language model may include an n-gram, exponential, positional, neural network, and/or other type of model.

A Large Language Model (“LLM”) is any type of language model that has been trained on a larger data set and has a larger number of training parameters compared to a regular language model. An LLM can understand more intricate patterns and generate text that is more coherent and contextually relevant due to its extensive training. Thus, an LLM may perform well on a wide range of topics and tasks. An LLM may comprise a NN trained using self-supervised learning. An LLM may be of any type, including a Question Answer (“QA”) LLM that may be optimized for generating answers from a context, a multimodal LLM/model, and/or the like. An LLM (and/or other models of the present disclosure), may include, for example, attention-based and/or transformer architecture or functionality. LLMs can be useful for natural language processing, including receiving natural language prompts and providing natural language responses based on the text on which the model is trained. LLMs may not be data security- or data permissions-aware, however, because they generally do not retain permissions information associated with the text upon which they are trained. Thus, responses provided by LLMs are typically not limited to any particular permissions-based portion of the model.

While certain aspects and implementations are discussed herein with reference to use of a language model, LLM, AI, and/or AI model, those aspects and implementations may be performed by any other language model, LLM, AI model, generative AI model, generative model, ML model, NN, multimodal model, and/or other algorithmic processes. Similarly, while certain aspects and implementations are discussed herein with reference to use of a ML model, language model, or LLM, those aspects and implementations may be performed by any other AI model, generative AI model, generative model, NN, multimodal model, and/or other algorithmic processes.

In various implementations, the LLMs and/or other models (including AI models and/or ML models) of the present disclosure may be locally hosted, cloud managed, accessed via one or more Application Programming Interfaces (“APIs”), and/or any combination of the foregoing and/or the like. Additionally, in various implementations, the LLMs and/or other models (including AI models and/or ML models) of the present disclosure may be implemented in or by electronic hardware such application-specific processors (e.g., application-specific integrated circuits (“ASICs”)), programmable processors (e.g., field programmable gate arrays (“FPGAs”)), application-specific circuitry, and/or the like. Data that may be queried using the systems and methods of the present disclosure may include any type of electronic data, such as text, files, documents, books, manuals, emails, images, audio, video, databases, metadata, positional data (e.g., geo-coordinates), geospatial data, sensor data, web pages, time series data, and/or any combination of the foregoing and/or the like. In various implementations, such data may comprise model inputs and/or outputs, model training data, modeled data, and/or the like.

Examples of models, language models, and/or LLMs that may be used in various implementations of the present disclosure include, for example, Bidirectional Encoder Representations from Transformers (BERT), LaMDA (Language Model for Dialogue Applications), PaLM (Pathways Language Model), PaLM 2 (Pathways Language Model 2), Generative Pre-trained Transformer 2 (GPT-2), GPT-3, GPT-4, GPT-4o, LLaMA (Large Language Model Meta AI), and BigScience Large Open-science Open-access Multilingual Language Model (BLOOM).

A Prompt (or “Natural Language Prompt” or “Model Input”) can be, for example, a term, phrase, question, and/or statement written in a human language (e.g., English, Chinese, Spanish, and/or the like), and/or other text string, that may serve as a starting point for a language model and/or other language processing. A prompt may include only a user input or may be generated based on a user input, such as by a prompt generation module (e.g., of a document search system) that supplements a user input with instructions, examples, and/or information that may improve the effectiveness (e.g., accuracy and/or relevance) of an output from the language model. A prompt may be provided to an LLM which the LLM can use to generate a response (or “model output”).

A User Operation (or “User Input”) can be any operations performed by one or more users to user interface(s) and/or other user input devices associated with a system (e.g., the data extraction system). User operation can include a request for task(s) to be performed, such as by using a machine learning model and/or an LLM, in whole or in part. User operation can include a request for data, such as data accessed and/or processed by one or more services. User operation can include one or more queries, one or more questions, one or more requests, or the like. User operation may include one or more natural language instructions for some data analysis (e.g., prediction, estimation, classification, or the like) to be performed. User operations can include, for example, select, drag, move, group, or the like.

Various combinations of the above and below recited features, embodiments, and aspects are also disclosed and contemplated by the present disclosure.

In various implementations, systems and/or computer systems are disclosed that comprise one or more computer-readable storage mediums or devices comprising, configured to store, and/or storing program instructions, and one or more processors configured to execute the program instructions to cause the systems and/or computer systems to perform operations comprising one or more aspects of the above- and/or below-described implementations (including one or more aspects of the appended claims).

In various implementations, computer-implemented methods are disclosed in which, by one or more processors executing program instructions, one or more aspects of the above- and/or below-described implementations (including one or more aspects of the appended claims) are implemented and/or performed.

In various implementations, computer program products comprising one or more computer-readable storage mediums or devices, and/or one or more computer-readable storage mediums or devices, are disclosed, wherein the computer-readable storage mediums comprise, are configured to store, and/or store program instructions, the program instructions executable by one or more processors to cause the one or more processors to perform operations comprising one or more aspects of the above- and/or below-described implementations (including one or more aspects of the appended claims).

### Example Operating Environment

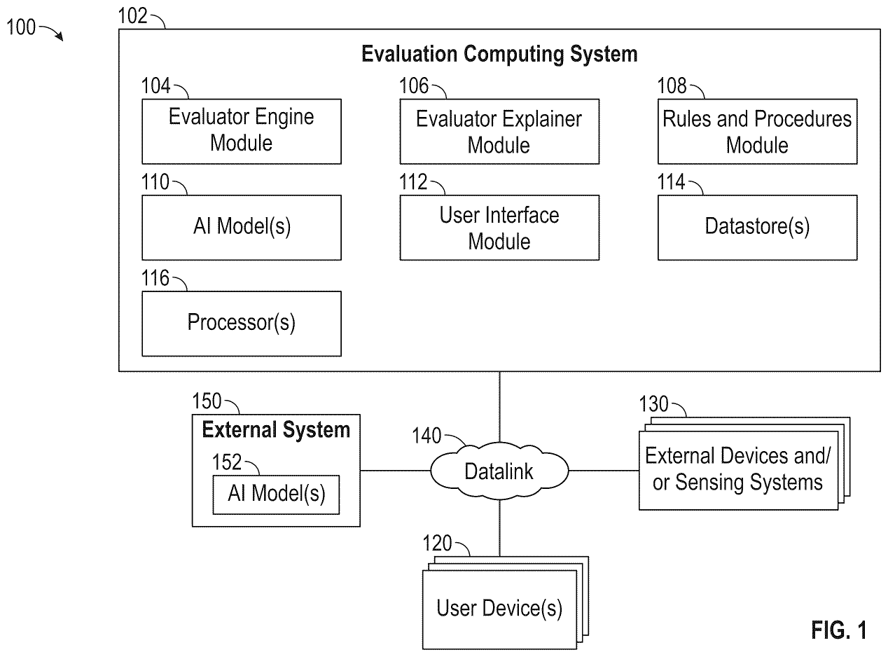

FIG. 1 illustrates a block diagram of an example operating environment 100 (which may also be referred to as an operational environment) in which one or more aspects of the present disclosure may operate, according to various implementations of the present disclosure. The operating environment 100 may include an evaluation computing system 102, one or more user devices 120, an external system 150, external devices and/or sensing systems 130, and a datalink 140. The evaluation computing system 102 can include an evaluator engine module 104, an evaluator explainer module 106, a rules and procedures module 108, one or more AI models 110, a user interface module 112, one or more datastores 114, and one or more processors 116.

Further details and examples regarding the implementations, operation, and functionality of the various components of the evaluation computing system 102 and the example operating environment 100 are described herein in reference to various figures.

### Datalink 140

The datalink 140 can include any wired network, wireless network, or combination thereof. For example, the datalink 140 can be a personal area network, local area network, wide area network, over-the-air broadcast network (e.g., for radio or television), cable network, satellite network, cellular telephone network, or combination thereof and/or the like. As a further example, the datalink 140 can be a publicly accessible network of linked networks, possibly operated by various distinct parties, such as the Internet. In various implementations, the datalink 140 may be a private or semi-private network, such as a corporate or university intranet. The datalink 140 can include one or more wireless networks, such as a Global System for Mobile Communications (GSM) network, a Code Division Multiple Access (CDMA) network, a Long Term Evolution (LTE) network, C-band, mmWave, sub-6 GHz, or any other type of wireless network. The datalink 140 can use protocols and components for communicating via the Internet or any of the other aforementioned types of networks. For example, the protocols used by the datalink 140 may include Hypertext Transfer Protocol (HTTP), HTTP Secure (HTTPS), Message Queue Telemetry Transport (MQTT), Constrained Application Protocol (CoAP), and the like. Protocols and components for communicating via the Internet or any of the other aforementioned types of communication networks are well known to those skilled in the art and, thus, are not described in more detail herein.

In various implementations, the datalink 140 can represent a network that may be local to a particular organization, e.g., a private or semi-private network, such as a corporate or university intranet. In various implementations, devices (e.g., evaluation computing system 102, external system 150, user devices 120, and external devices and/or sensing systems 130) may communicate via the datalink 140 without traversing an external network, such as the Internet. In various implementations, devices connected via the datalink 140 may be walled off from accessing the Internet, e.g., the datalink 140 may be or may not be connected to the Internet. Accordingly, e.g., the user device(s) 120 may communicate with the evaluation computing system 102, external system 150, or external devices and/or sensing systems 130 directly (via wired or wireless communications) or via the datalink 140, without using the Internet. Thus, even if the datalink 140 or the Internet is down, the user device(s) 120, the evaluation computing system 102, the external system 150, and/or the external devices and/or sensing systems 130 may continue to communicate and function via direct communications (and/or via the datalink 140).

In various implementations, the datalink 140 and/or various other aspects of the operating environment 100 can incorporate “mesh” type communications among components, and/or secure communications among components. Examples of such mesh and/or secure communications are described in U.S. Patent Publication No. 2019/0380032, published Dec. 12, 2019, and titled “Lattice Mesh” (the '032 Publication), the entire disclosure of which is hereby made part of this specification as if set forth fully herein and incorporated by reference for all purposes, for all that it contains. For example, and in various implementations as described herein, detection and/or identification of object(s), and/or responding to such a detection and/or identification can be performed by one more systems, devices, sensors, or the like. For instance, any devices and/or sensors can communicate with one or more of the evaluation computing systems described herein so that any information transmitted between devices can be used, in whole or in part, to initiate a response.

### External Devices and/or Sensing Systems 130

The external devices and/or sensing system 130 can include various components for detecting objects within an operating environment. The external devices and/or sensing systems 130 can include, for example, various sensors and monitoring equipment. For example, non-limiting examples of external devices and/or sensing systems 130 can include: sensors/monitors (e.g., temperature, positioning/location, PNT, direction finder, altitude, angle/tilt, levels, vibration, power, pressure, and/or the like); video cameras (e.g., video, audio, position, motion, heat, and/or the like); antennas (e.g., long range, short range, and/or the like); radar devices; light detection and ranging (“LIDAR”) devices; laser detection and ranging (“LADAR”) devices; mobile systems or sensors (e.g., a sensor on a vehicle or an aerial drone); stationary systems or sensors (e.g., a sensor on a tower station); other types of systems or sensors; and/or any combination of the foregoing. Additional examples of external devices and/or sensing systems 130 that can be included in the operating environment 100, and which can provide information to, or receive information from, the evaluation computing system 102, as described herein, are described in U.S. Patent Application Publication No. 2020/0167059, filed Nov. 27, 2018, and titled “Interactive Virtual Interface” (the '059 Publication), and in U.S. Patent Application Publication No. 2020/0363824, filed May 17, 2019, and titled “Counter Drone System” (the '824 Publication), the entire disclosures of each of which are hereby made part of this specification as if set forth fully herein and incorporated by reference for all purposes, for all that they contain.

As described herein, the evaluation computing system 102 can communicate with, provide information to, or receive information from, the external devices and/or sensing systems 130. In various embodiments, communications among the various components of the operating environment 100 may be accomplished via intermediate communications with a centralized server or database (e.g., the evaluation computing system 102 or external system 150), which may store data associated with the external devices and/or sensing systems 130. Alternatively, the external devices and/or sensing systems 130 can be communicated with and/or configured via communication with user device(s) 120. Data and information gathered from the external devices and/or sensing systems 130 may be provided directly or indirectly to the evaluation computing system 102.

In various implementations, one or more of, or a combination of, the evaluation computing system 102, sensing systems 130, external system 150 and/or the user device(s) 120 can provide an application programming interface (“API”) by which communications can be accomplished with the external devices and/or sensing systems 130.

The various communications among the components of the operating environment 100 can, as described herein, be used to determine locations of objects (which may include mobile objects) via various methods. Examples of such communications and methods of determining locations of objects are provided in, for example, the '059 Publication and the '824 Publication.

### Evaluation Computing System 102

The evaluation computing system 102 can receive information from the device(s) 120, external system 150, and external devices and/or sensing systems 130. The evaluation computing system 102 can use the received information to generate options of potential actions between the objects, generate overviews and summaries of the options, generate follow up explanations of the options, evaluate the applicability of one or more rules and procedures for the options, and/or perform other functionality described herein. The evaluation computing system 102 can include, for example, one or more computing systems in communication (e.g., via datalink 140) with the device(s) 120, external devices and/or sensing systems 130, and/or external system 150. For example, data and information gathered from the external devices and/or sensing systems 130 can be provided directly or indirectly to the evaluation computing system 102 for storage, analysis, and/or transmission to other connected systems. For example, one external device and/or sensing system 130 might detect/identify a specific signal and/or object, and the external device and/or sensing system 130 can transmit that data to the evaluation computing system 102. For example, in some examples described herein, the external devices and/or sensing systems 130 can work together in a network to detect signals around a designated area or location (e.g., a building).

As noted above, the various components of the operating environment 100 can, as described herein, be used to determine locations of objects (which may include mobile objects) via various methods. Examples of such methods of determining locations of objects are provided in, for example, the '059 Publication and the '824 Publication. Accordingly, the evaluation computing system 102 and/or user device(s) 120 of the present disclosure can be analogous, in whole or in part, to the interactive virtual interface system of the '059 Publication in that various sensor data and location determinations may be integrated together. Such location information may further be shared among the various components of the operating environment 100 to enable coordination among the components for transmitting generated signals to located objects (which may include mobile objects). Further, as noted above, communications among the various components of the operating environment 100 can be provided via various methods, some examples of which are described in the '032 Publication.

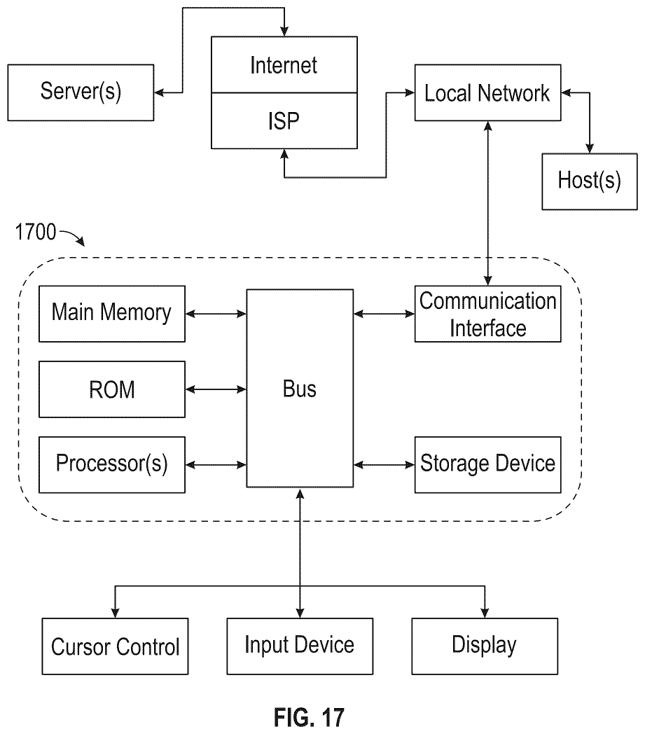

In various implementations, the evaluation computing system 102 can comprise hardware similar to that of the computer system described herein in reference to FIG. 17. Alternatively, in various implementations, the evaluation computing system 102 can exist via software. In various implementations, the evaluation computing system 102 can create a mesh network, an example of which is described in the '032 Publication (as noted above). For example, the evaluation computing system 102 can comprise an interface and processor(s) 116. The interface can be configured to receive a request to register from a host, wherein the request to register includes a key and a set of asset identifications (“IDs”) that the host wishes to claim. The processors 116 can be configured to sign the key to generate a resource authority (“RA”) certificate signed key with an RA certificate; update an asset database with the RA certificate signed key; distribute the RA certificate signed host public key through the datalink 140; and provide the host with the RA certificate signed key. In various implementations, the evaluation computing system 102 can further comprise a datastores (e.g., a memory) that are coupled to the processors 116 and configured to provide the processors 116 with instructions. The system for a mesh network can include a secure mechanism for communication between nodes (e.g., evaluation computing system 102, external devices and/or sensing systems 130, user devices 120, and/or the like) that is enabled for messages that have a targeted destination both in a point-to-point mode and a publication mechanism where a message can be targeted at multiple destinations. The security for the communications can be designed to prevent compromised nodes from being used to acquire significant message traffic from the network once the node is compromised. In addition, the network can prioritize real-time data despite variable performance of network links. The network can also ensure security by establishing secure routing by using point to point authorizations. The network can also strategically cache data flowing in the network so that when channels are available data can be sent. The mesh network can be an improvement over other networks by improved security. The network can be designed to overcome unstable communication links and the potential for nodes becoming compromised. The mesh network can overcome potential issues by using security systems that secure messages, secure routes, and secure backfilling of messages that wait to be sent through the network.

In various implementations, the evaluation computing system 102 can provide an application programming interface (“API”) by which communications can be accomplished external system 150, external devices and/or sensing systems 130, and/or user device(s) 120. For example, data collected or generated by an external device and/or sensing system 130 can be sent to evaluation computing system 102 to be combined with other data collected (e.g., from other external devices and/or sensing systems 130) and stored for later transmission to any system on the network or outside of the network (e.g., via the internet and by using an API).

### Evaluator Engine Module 104

As noted above, in various implementations, the evaluation computing system 102 can be used to determine locations of objects (which may include mobile objects) via various methods. These locations of objects can be used to determine an operating environment for a the objects. Additionally, or alternatively, the evaluation computing system 102 may simulate one or more objects within the operating environment and/or populate an operating environment with data retrieved from memory (such as in one or more datastore(s) 114). The evaluator engine module 104 can use tracked information in the operating environment and accessed information (e.g., information received by the evaluation computing system 102 and/or retrieved from one or more datastore(s) 114) to determine options of potential actions between objects within the operating environment. The options can be in response to a determined task given to the evaluator engine module 104.

The accessed information can include properties (e.g., velocity, range, capacity, and/or the like) and rules (e.g., threshold requirements, tracking requirements, required procedures, and/or the like) of various object types. The accessed information can also include relationships between object types (e.g., percentages of success between Object A and Object B for a given task). Examples, of accessed information are illustrated in FIG. 11 and FIG. 12.

The information and logic used by the evaluator engine module 104 to determine the options (collectively referred to herein as the “evaluator engine logic”) can be tracked and stored (e.g., in the datastore(s) 114) for use by the evaluator explainer module 106. Examples of evaluator engine logic can include, but is not limited to, rules applied to the objects, information accessed in association with the objects, the current state of the operating environment, and/or other suitable information.

The evaluator engine module 104 can include software and hardware components for determining the options. For example, the evaluator engine module 104 can use include instructions for a processor to perform the above described steps. In various implementations, the evaluator engine module 104 can include and/or use one or more AI models configured to take as input information associated with the operating environment, the accessed information, and, an associated task, and output options of potential actions between objects for accomplishing the task and the evaluator engine logic used to come to the determination. However, in various implementations, no AI models are included and/or used by the evaluator engine module 104.

### Evaluator Explainer Module 106

As described above, an evaluator explainer module 106 can include and/or interface with one or more AI models 152, 110, such as language models, LLMs, and/or other AI models. Some, or all, of the AI models can be stored and/or implemented on the evaluation computing system 102 (e.g., the models 110) and/or implemented on an external system 150 and accessed (e.g., using an API).

Evaluator explainer module 106 can generate a prompt using the information used to generate options, the evaluator engine logic, and, in some instance, input from a user. In various implementations, the evaluation explainer may generate the prompt for an AI model by populating a template prompt with the information used to generate options, the evaluator engine logic, and the input from the user. Some, or all, of this information may be dynamically determined at the time the prompt is generated. The template prompt may also include instructions (e.g., static descriptions or instructions) to the AI model on what to do with the information.

As stated above, some portions of the prompt can be dynamic. For example, tables of data may be populated into the prompt based on real-time updates at the time the prompt was generated. Some information the evaluator explainer module 106 provides to the AI model may be temporality retained by the AI model and/or saved in the evaluation computing system 102 and used in follow on prompts generated and sent to the AI model (e.g., along with the user input questions). For example, current states of the objects (e.g., position, velocity, bearing, and/or other suitable indication of object state), static contextual information (e.g., tables of data, relevant rules, and/or other relevant static contextual information), and/or information used for user display preferences (e.g., embedded html tags) can be provided to the AI model and maintained by the AI model and/or system throughout the various processes performed by the evaluator explainer module 106.

After the evaluator explainer module 106 provides the generated prompt to the AI model, the evaluator explainer may receive and display a result from the AI model to a user (e.g. on a graphical user interface of user device(s) 120 via the user interface module 112). In various implementations, the results are displayed on a graphical user interface along with the task to be performed, the potential options for accomplishing a task, the relevant objects (e.g., all the object in a particular geographic area considered by the evaluator engine), and/or other information. In various implementations, rather than displaying the result on the graphical user interface, an indication of the result is displayed on the graphical user interface (e.g., an indication that a summary has been generated). The results can then be displayed based on a user input interacting with the indication (e.g., a mouse click on the indication or hovering a cursor over the indication).

In various implementations, multiple interactions between the evaluator explainer module 106 and an AI model may be triggered by a single user input. In an illustrative example, a graphical user interface may display objects and potential actions between the objects. A user may select an option on the graphical user interface to initiate the evaluator explainer. This selection may trigger the evaluator explainer module 106 to generate a prompt for the AI model using the potential actions, the evaluator engine logic used to determine the potential actions, the relevant information used by the evaluator engine, and instructions to generate an overview of the potential actions (e.g., using a template prompt described above). The evaluator explainer module 106 can then provide the prompt to the AI model and receive a response from the AI model with the generated overview of the potential actions. The evaluation computing system 102 can display the overview to a user on the graphical user interface (e.g., on a graphical user interface of user device(s) 120 via the user interface module 112).

In an illustrative example, without further user input, the evaluator explainer module 106 can generate one or more subsequent prompts for generating summaries for each of the potential options. The prompts can each include a particular potential action to summarize, associated evaluator engine logic and relevant information used by the evaluator engine to determine the particular potential action, and instructions to generate a summary of the particular potential action. The system can provide the subsequent prompts to the AI model, receive response from the AI model, and display indications of the summaries of the options of potential actions on the graphical user interface. In various implementations, rather than providing separate prompts, the system can generate a prompt that includes the above described information and instructions to generate and overview of the options and a summary of each individual option in a single prompt.

In some instances, the user may desire further information regarding the generated options. The evaluator explainer module 106 may generate, automatically or in response to a user input, and display a field for the user to input questions associated with the options. The user input can be in plain language (e.g., a plain English question). For example, the user input can be the text string, “Why did option 1 fail a test?”. The user input can be included in a generated prompt in a similar manner as described above (e.g., using a template) along with the needed contextual information (e.g., the information used to generate options and logic used by the evaluator engine) and provided to the AI model. In various implementations, the AI model or system may retain contextual information, which may simplify the prompt. The evaluator explainer may receive an AI model response and display the response on the graphical user interface. The evaluator engine may receive additional user input and repeat the process described above to generate AI model prompts and receive and display AI model responses. In various implementations, the user input and the AI model responses may be displayed together on the graphical user interface.

The various AI model responses may include answers in more than one language. In various implementations, the AI model responses of different languages may be determined separately, meaning that the AI model can generate the response in a first language and a response in a second language, using the same information, rather than generating a response in the first language and translating the response to the second language. In various implementations, the languages may be translated.

The evaluator explainer module 106 can include various instructions (e.g., instructions stored on a memory, such as datastore(s) 114 and provided to one or more processors 116) to cause the evaluation computing system 102 to perform the operation described above and elsewhere herein.

### Rules and Procedures Module 108

As described above, evaluation computing system 102 can (e.g., by using an evaluator explainer module 106) can receive tracked information and a task to be performed and determine options of potential actions between objects to accomplish the task. A set of rules and procedures may dictate whether each of the determined potential actions are permitted to be performed, influence how one or more of the potential actions should be performed, and/or otherwise dictate or influence the performance of potential actions. As a potential effect of the rules and procedures, actions (e.g., potential actions between objects) that are theoretically possible (e.g., the actions could be performed given object capabilities and current conditions) may not be viable or permitted because the action is counter to the rules and procedures.

As also noted above, the rules and procedures can include a large amounts of information (e.g., 10s, 100s, 1000s, or more pages or documents of documentations). Further, in some instances, the rules and procedures may be dynamic and ever evolving (e.g., the rules and procedures may be continually updated). Furthermore, some of the rules and procedures may have a relatively high level of specificity and/or have relatively narrow applicability. For example, some of the rules and procedures may be specific to an object type, an object, a property of an object or object type, an operating environment, and/or specific to other information used to determine and/or execute an action. Accordingly, it can be difficult to determine when any of the rules and procedures apply to a given action, which of the rules and procedures apply to a given action, whether any of the rules and procedures prevent or change the given action, and/or whether the rules and procedures influence the given action in other ways.

The rules and procedures module 108 can address the above mentioned, and other technical problems, that can arise from the rules and procedures. According to various implementations, the rules and procedures module 108 can determine applicable portions of a set of rules and procedures (referred to herein as “logical blocks” of the set of rules and procedures) and determine whether potential actions between objects comply with the rules and procedures. The rules and procedures model can include and/or interface with AI models, such as LLMs, which can perform some of the operations of the rules and procedures module described herein.

In various implementations, the rules and procedures module 108 can access information indicating potential actions between objects. The information could be generated or determined by the evaluation computing system 102 (e.g., by using an evaluation engine module 104), entered by a user (e.g., by one or more user inputs) and/or otherwise generated or determined. The rules and procedures module can use the accessed information and a set of rules and procedures to determine whether potential actions comply with the set of rules and procedures. In various implementations, the rules and procedures module 108 can automatically begin the determination. In other implementations, the rules and procedures module 108 can begin the determination based on user input (e.g., a user selecting a potential action on a graphical user interface or a user entering a potential action for the system to check on the graphical user interface). As described above, the set of rules and procedures can include a relatively large amount of information. As such, the set of rules and procedures may be too large to be referenced in some situations. For example, the set of rules and procedures may be too large to provide to an AI model in a prompt (e.g., the set of rules and procedures exceeds a character limit and/or would take an impractically long time to process).

The rules and procedures module 108 can determine logical blocks from a set of rules and procedures related to the potential actions and/or the objects. In various implementations, the rules and procedures module 108 can determine the logical blocks by using a similarity search on the set of rules and procedures. The similarity search can include searching the set of rules and procedures for words or phrases associated with the potential actions and/or the objects. The logical blocks can be documents of set of rules and procedures where the words or phrases occur, pages of the set rules and procedures where the words or phrases occur, sections of the set rules and procedures where the words or phrases occur, sentences of the set rules and procedures where the words or phrases occur, and/or other partitions of the set of rules and procedures associated with the words or phrases. In various implementations, the rules and procedures module 108 can determine the logical blocks using other techniques. For example, using metadata to associate the potential actions and/or objects to portions of the set of rules and procedures.

In an example, one potential action could be for a vehicle (e.g., an object) to drive (e.g., potential action) to a building (e.g., a second object). In this example the similarity search can include: a search of the vehicle make and model, a search on the location/orientation of the vehicle (e.g., as indicated in the accessed information), a search of drive (or other synonymous terms or phrases), a search on the location of the building and/or other words or phrases associated with the vehicle, driving, or building. The result of this example search could include logical blocks such as: operations manuals of the vehicle, documentation of a projected route (e.g., road types, speed limits, and/or the like), and/or documentation associated with the building, to list a few examples.

The rules and procedures module 108 can use the determined logical blocks of the set of rules and procedures in a prompt to an AI model. In various implementations, the rules and procedures module 108 can generate a prompt for an AI model that includes the one or more potential actions, the accessed information, the determined logical blocks from the set of rules and procedures, and instructions for the AI model to generate indications of whether the each of the potential actions complies with the provided rules and procedures. In various implementations, the prompt can include other information and/or omit some of the above mentioned information. The rules and procedures module 108 can provide the prompt to the AI model. The rules and procedures module 108 can generate the prompt in a similar manner as the evaluator explainer (e.g., using a template prompt with static and dynamic portions).

The rules and procedures module 108 can receive a response from the AI model with the indications of whether each of the potential actions complies with the set of rules and procedures. The rules and procedures module 108 can cause a graphical user interface to display each of the potential actions along with an associated indication of whether the potential action complies with the set of rules and procedures.

In some instances, a user may wish to perform a potential action indicated by the rules and procedures module 108 as not complying the set of rules and procedures and/or may otherwise wish to receive authorization for the potential action. According to various implementations, a user may select a particular potential action associated with an indication that the particular action does not comply with the set of rules and procedures. The rules and procedures module 108 can receive the user input and send and/or cause the particular potential action to be displayed to a user with authority to authorize the potential action. In various implementations, the particular action is displayed to the user with authority to authorize the potential action on a different graphical user interface than was used by the user wishing to perform the potential action. For example, the user with authority to authorize the potential action may have access to a graphical user interface that includes the capability to provide authority to perform actions (e.g., via one or more buttons, fields, and/or the like, of the graphical user interface.). The rules and procedures module 108 can receive an input from the separate graphical user interface with an authorization from the user with authority permitting (or authorizing) the particular action to be performed. The rules and procedures module 108 can generate an alert and display (e.g., on a graphical user interface) the alert to the user wishing to perform the potential action that the potential action has been authorized.

According to various implementations, when the authorization is received the rules and procedures module 108 (or other components of the system) may perform one or more operations. For instance, the rules and procedures module 108 (or other components of the system) may redetermine and/or update the potential actions, the objects, logical blocks of the set of rules and procedures, to reflect the authorization (and any other changes that may have occurred in the interim). As such, some of the potential actions determined before may be removed and/or some additional potential actions and associated objects may be added based on the authorization and/or other changes that occurred. Similarly, the logical blocks may be different based on the change in the potential actions, objects, and/or based on the authorization.

The rules and procedures module 108 can generate a second prompt for an AI MODEL that includes the potential actions, the accessed information, and the logical blocks from the set of rules and procedures, some, or all, of which may have been updated. The prompt can also include the authorization and instructions, including instructions to generate updated indications of whether each of the potential actions complies with the set of rules and procedures. The system can generate the prompt, receive a response with the indications and display the indications in a manner similar as is described above with respect to the first interaction with the AI model.

In various implementations, some, or all of the information used and generated by the rules and procedures module 108 may be tracked and/or recorded in a log. For example, the rules and procedures module 108 may track the accessed information, the potential actions, the logical blocks, the generated prompts, the responses received from an AI model, requests for authorization of potential actions, authorizations, and/or other information used or generated by the rules and procedures module 108 or users may be tracked and/or recorded in a log. The log, or a portion of the log, can be presented to a user (e.g., a human in the loop) via another graphical user interface (e.g., a third graphical user interface). The rules and procedures module 108 can receive input from the user verifying or correcting one or more items of the log. For example, the user may verify or correct the determined logical blocks, the indications whether a potential action complies with the set of rules and procedures, the set of rules and procedures, authorizations to perform particular potential actions, and/or other information in the log. The rules and procedures module 108 can record the verifications and corrections. The rules and procedures module 108 then reperform any of the above described operations in light of the recorded verifications and corrections. For example, the rules and procedures module 108 may redetermine the potential actions, the objects, and the logical blocks and regenerate a prompt to the AI model based on the recorded verifications and corrections.

The various AI model responses may include answers in more than one language. In various implementations, the AI model responses of different languages may be determined separately, meaning that the AI model can generate the response in a first language and a response in a second language, using the same information, rather than generating a response in the first language and translating the response to the second language. In various implementations, the languages may be translated.

The rules and procedures module 108 can include various instructions (e.g., instructions stored on a memory, such as datastore(s) 114 and provided to one or more processors 116) to cause the evaluation computing system 102 to perform the operation described above and elsewhere herein.

### User Interface Module 112

The user interface module 112 can facilitate the generation and maintenance of one or more graphical user interfaces on the user devices 120. The graphical user interfaces can be generated and maintained on the evaluation computing system 102 and accessed by the device(s) 120 via the datalink 140 (e.g., in a portal or application), generated and maintained on the device(s) 120 based on information received from the datalink 140, or implemented as combination of each.

In various implementations, the graphical user interface provided and implemented on the user devices 120 can comprise relatively streamlined interactive graphical user interfaces. For example, the interactive graphical user interfaces displayed on the user devices 120 can comprise relatively few large buttons by which a user can select to stop a currently running configuration, can select a different configuration from a list, can search for a different configuration, and/or can monitor a current status of inputs/outputs, analyses, machine learning models, and/or the like (and as noted above).

Additionally, it has been noted that design of computer user interfaces that are useable and easily learned by humans is a non-trivial problem for software developers. The present disclosure describes various implementations of interactive and dynamic graphical user interfaces that are the result of significant development. This non-trivial development has resulted in the graphical user interfaces described herein which can provide significant cognitive and ergonomic efficiencies and advantages over previous systems. The interactive and dynamic graphical user interfaces include improved human-computer interactions that can provide reduced mental workloads, improved decision-making, improved capabilities, reduced work stress, and/or the like, for a user. For example, user interaction with the interactive graphical user interface via the inputs described herein can provide an optimized display of, and interaction with, video gateway devices or controller devices, and can enable a user to more quickly and accurately access, navigate, assess, and digest analyses, configurations, received/operational data, and/or the like, than previous systems.

Further, the interactive and dynamic graphical user interfaces described herein are enabled by innovations in efficient interactions between the user interfaces and underlying systems and components. For example, disclosed herein are improved methods of receiving user inputs (including methods of interacting with, and selecting, received data), translation and delivery of those inputs to various system components (e.g., the evaluation computing system 102), automatic and dynamic execution of complex processes in response to the input delivery (e.g., execution of the evaluator engine module 104, evaluator explainer module 106 and/or rules and procedures module 108), automatic interaction among various components and processes of the system, and automatic and dynamic updating of the user interfaces (to, for example, display the information related to the execution of the evaluator engine module 104, evaluator explainer module 106 and/or rules and procedures module 108). The interactions and presentation of data via the interactive graphical user interfaces described herein may accordingly provide cognitive and ergonomic efficiencies and advantages over previous systems.

### Datastore(s) 114

The datastores 114 can include various computer-readable storage mediums. For example the datastore(s) 114 can include a portable computer diskette, a hard disk, a solid-state drive, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, other suitable storage medium, or any suitable combination of the foregoing.

The datastores 114 can include software instructions for executing the various processes or functions described herein, such as those performed by the evaluator engine module 104, evaluator explainer module 106, and rules and procedures module 108. The datastore 114 can also include information (or data) used in such processes or functions, such as information received from external devices and/or sensing systems 130, information associated with a current state of an operating environment, information associated with objects within the operating environment, information used by the evaluator engine module 104 in determining options of potential actions for performing a task, information used in generating prompts, rules and procedures information, and/or any other information that is accessed by the evaluation computing system 102 or from elsewhere in the operating environment 100 in performing the operations described herein.

### AI Model(s) 110

The evaluation computing system 102 may include and/or interface with one or more AI models 110. The AI models can include any of the AI models described herein, including, but not limited to, language models, LLMs, artificial neural networks, and/or machine learning models. The AI models 110 may be partially or fully implemented outside the evaluation computing system 102, for example by the external system 150, and accessed (e.g., using an API). In various implementations, the AI models 110 are trained by a different computing system, such as the external system 150, a specific instance of one or more of the AI models 110 may be implemented on the evaluation computing system 102.

The AI models 110 can be incorporated into the various functionality of the evaluation computing system 102 described herein. For example, the evaluator engine module 104, the evaluator explainer module 106, and the rules and procedures module 108 may each utilize one or more of the AI models 110.

### Processor(s) 116

Any of the processes, methods, algorithms, elements, blocks, applications, or other functionality (or portions of functionality) performed by the evaluation computing system 102 may be embodied in, and/or fully or partially automated via, one or more processors and/or electronic hardware such application-specific processors (e.g., application-specific integrated circuits (ASICs)), programmable processors (e.g., field programmable gate arrays (FPGAs)), application-specific circuitry, and/or the like (any of which may also combine custom hard-wired logic, logic circuits, ASICs, FPGAs, and/or the like. With custom programming/execution of software instructions to accomplish the techniques). The processors can include central computational units (CPUs), graphics processing units (CPUs), controllers, and/or any other suitable component for executing computer-executable instructions.

### External System 150

The external system 150 can comprise one or mor computing devices and perform one or more of operations described with respect to the user device(s) 120, the external devices and/or sensing systems 130, and/or the evaluation computing system 102. The external system 150 can include one or more AI models 152. The AI models 152 can include any of the AI models 110. In various implementations, AI models 152 perform some, or all, of the functionality of the AI models 152. For example, the one or more AI models 152 can perform functionality of the evaluator engine module 104, the evaluator explainer module 106, and the rules and procedures module 108 may each utilize one or more of the AI models 110.

### User Device(s) 120

The user device(s) 120 can comprise computing devices that provide a means for a user or admin to interact with a device (e.g., the evaluation computing system 102, the external system 150, the external devices and/or sensing systems 130, and/or other user devices 120). User devices 120 can comprise user interfaces or dashboards that enable communications between a user and a machine, system, or device, commonly used in industrial processes. In various implementations, user device(s) 120 comprise computer devices with a display and a mechanism for user input (e.g., mouse, keyboard, voice recognition, touch screen, and/or the like). In various implementations, the user device(s) 120 comprise tablet computing devices, laptop computing devices, or smart phones.

As noted above, the user device(s) 120 can communicate with the evaluation computing system 102, the external system 150, the external devices and/or sensing systems 130, and/or other user devices 120 via direct (e.g., not via a network) wired and/or wireless communications, and/or via a network (e.g., a local network) wired and/or wireless communications. In various implementations, the evaluation computing system 102 can provide configured interactive user interface remotely to any user devices 120 in communication with the evaluation computing system 102. Advantageously, such functionality can enable remote and centralized configuration of interactive user interfaces without requiring direct programming or interaction with each of the user device(s) 120.

In various implementations, a user can operate the evaluation computing system 102 via one or more graphical user interfaces accessible via device(s) 120. Via such user interfaces, the user can select tasks to be performed, view options of potential actions to accomplish the task, enter user input initiating the evaluator explainer module 106, view overviews of the options, select and/or view summaries of each options, enter text inquiries associated with the options, view responses associated with the inquiries, select which option to execute and/or perform any other user interaction or display described herein.

### Example Implementations of an Operational Environment

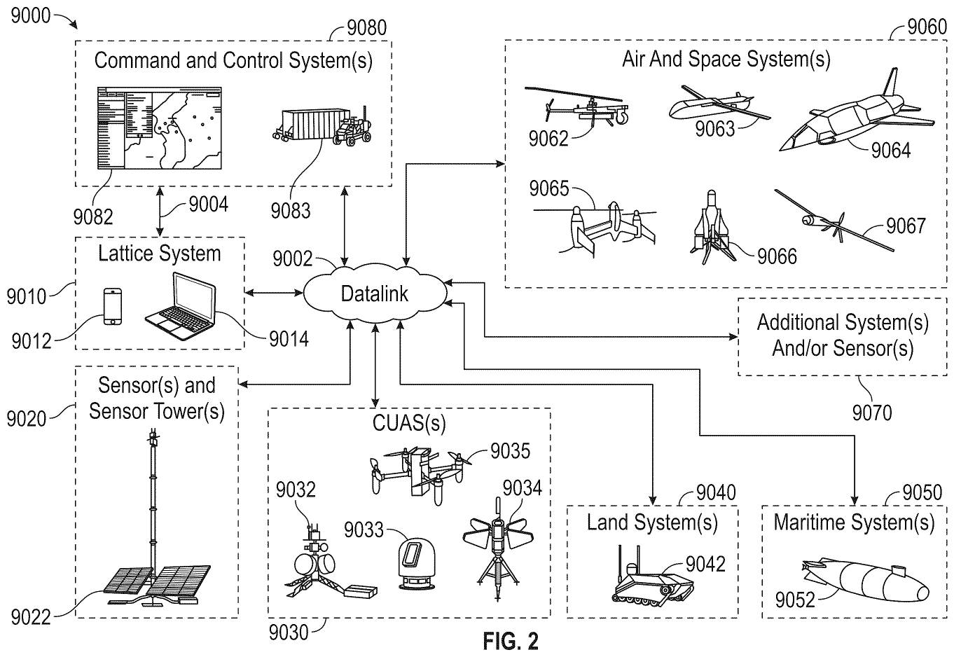

FIG. 2 illustrates a block diagram of a further example operational environment 9000 of the system, according to various implementations. The example operational environment 9000 can be similar to, or the same as, or include components similar to the operating environment 100 described in reference to FIG. 1. The operational environment 9000 can include one or more evaluation computing systems 102, user devices 120, or external systems 150 (e.g., Lattice system 9010, command and control system(s) 9080, and/or other components described below in reference to FIG. 2), one or more external devices and/or sensing systems 130 (e.g., various, vehicles, sensors, and systems described below in reference to FIG. 2), one or more networks or datalinks 140 (e.g., various networks and/or datalinks described below in reference to FIG. 2), and/or additional components as described herein.

The operational environment 9000 optionally includes, for example, vehicles such as land system(s) 9040, maritime system(s) 9050, air and/or space system(s) 9060, and/or counter unmanned arial system(s) 9030 (referred to herein as CUAS(s) 9030). As also illustrated, the operational environment 9000 optionally includes, for example, one or more external computing devices such as a Lattice system 9010, control and communications system(s) 9080 (such as, e.g., Menace), and/or the like. As further illustrated, the operational environment 9000 optionally includes, for example, data sources and/or sensors such as one or more sensor(s) and/or sensor tower(s) 9020, and/or CUAS(s) 9030. As also illustrated, the operational environment 9000 optionally includes, for example, networks and/or datalinks such as network and/or datalink 9002 which provide communications among the various components of the operational environment 100. In some cases, the operational environment 100 also includes various direct and/or alternative communications links among various components, such as communications link 9004 between the Lattice system 9010 and the control and communications system 9080.

The groupings of components in the example operational environment 9000 illustrated in FIG. 2 and described above is illustrative and not limiting. For example, various components are organizable into groups different from those described above, and/or into multiple groups. For example, in various implementations any of the various vehicles (e.g., land system 9040, maritime systems 9050, and/or air and space systems 9060) also include sensor and/or data source functionality by way of various sensors (e.g., cameras, radar devices, external devices and/or sensing systems 130, and/or any other sensors 9070) included in or on those vehicles. Similarly, any of the various sensors (e.g., sensors and sensor towers 9020, CUASs 9030, and/or the like) optionally also comprise and/or are associated with vehicles. Further, in some cases, the operational environment 9000 includes components different from those described in reference to FIG. 2, and/or additional system(s) (e.g., vehicles, computing systems, and/or the like) and/or sensor(s) 9070.

Sensors and sensor towers 9020 include, for example, a sentry tower 9022. Examples of such sensor towers and associated functionality are described in U.S. Patent Publication No. 2022/0377232, published Nov. 24, 2022, and titled “Auto-Focus Acquisition For Remote Flying Targets” (the '232 Publication), the entire disclosure of which is hereby made part of this specification as if set forth fully herein and incorporated by reference for all purposes, for all that it contains.

CUASs 9030 include, for example, a long-range sentry tower 9032, a wide-area infrared system for persistent surveillance (WISP) 9033, a software-defined electromagnetic warfare (EW) device/system (e.g., a Pulsar system) 9034, and/or an autonomous counter unmanned arial system drone device (e.g., an Anvil device) 9035. CUASs 9030, in some cases, include various autonomous functionalities, such as movement, goal seeking, ISR, and/or the like. Examples of such Pulsar systems and associated functionality are described in PCT International Publication No. 2023/225417, published Nov. 23, 2023, and titled “Modular System For Detecting, Tracking, And Transmitting To Identified Objects” (the '417 Publication), the entire disclosure of which is hereby made part of this specification as if set forth fully herein and incorporated by reference for all purposes, for all that it contains. Examples of such Anvil devices and associated functionality are described in U.S. Patent Publication No. 2020/0363824, published Nov. 19, 2020, and titled “Counter Drone System” (the '824 Publication), the entire disclosure of which is hereby made part of this specification as if set forth fully herein and incorporated by reference for all purposes, for all that it contains.

Land systems 9040 include, for example, various land-based vehicles 9042, such as automobiles, tanks or other armored vehicles, all-terrain vehicles, and/or the like. Land systems 9040, in some cases, include various autonomous functionalities, such as movement, goal seeking, ISR, and/or the like.

Maritime systems 9050 include, for example, a boat, a ship, and/or a submarine 9052. Maritime systems 9050, in some cases, include various autonomous functionalities, such as movement, goal seeking, ISR, and/or the like.

Air and/or space systems 9060 include, for example, an extended-range unmanned aircraft system (UAS) 9062, an air-breathing autonomous air vehicle (AAV) 9063, a group 5 AAV 9064, a tandem rotor AAV 9065, a vertical take-off and landing (VTOL) AAV 9066, an autonomous launch effect 9067, an airplane, a balloon, a missile, a rocket, a satellite, and/or the like. Examples of such UASs and associated functionality are described in U.S. Patent Publication No. 2020/0126431, published Apr. 23, 2020, and titled “Ruggedized Autonomous Helicopter Platform” (the '431 Publication), the entire disclosure of which is hereby made part of this specification as if set forth fully herein and incorporated by reference for all purposes, for all that it contains. Examples of such tandem rotor AAVs and associated functionality are described in U.S. Patent Publication No. 2024/0262489, published Aug. 8, 2024, and titled “Dual Engine Vertical Take Off And Landing Collapsible Fixed Wing Aircraft” (the '489 Publication), the entire disclosure of which is hereby made part of this specification as if set forth fully herein and incorporated by reference for all purposes, for all that it contains. Examples of such autonomous launch effect and associated functionality are described in U.S. Pat. No. 9,545,991, issued Jan. 17, 2017, and titled “Aerial Vehicle With Deployable Components” (the '991 Patent), the entire disclosure of which is hereby made part of this specification as if set forth fully herein and incorporated by reference for all purposes, for all that it contains.

In various implementations, and as described above, various components of the operational environment 9000 advantageously include autonomous functionality. This means, for example, that submarine 9052 and/or VTOL AAV 9066 is able to operate and pursue mission objectives and/or tasks autonomously. Such components, in some cases, also are able to autonomously coordinate with each other in pursuit of mission objectives and/or tasks.

In various implementations, various components of the operational environment 9000 include munitions capabilities. Such capabilities, in some cases, are used by these components in pursuit of mission objectives and/or tasks.

In various implementations, and as described above, various vehicles and systems of the operational environment 9000 include sensor, munitions, and/or other functionality specific to the types of vehicles or systems. For example, in some cases a submarine includes SONAR functionality, a UAS or AAV includes camera functionality, and a sensor tower includes radar functionality.

In some examples, the Lattice system 9010 comprises a software platform advantageously capable of being used for a variety of missions and industries. The Lattice system 9010 communicates with any type of sensor, network, and/or system, and receives, integrates, and/or sends data and/or communications. The Lattice system 9010 moves data received from the various systems with which it communicates into a single integration layer that uses AI, machine learning, and/or sensor and data processing techniques to, e.g., filter high-value information to users. The filtering and the functionality of the Lattice system 9010 advantageously enables quick reactions to the data by tasking other systems such as sensors, vehicles, or other assets within and via the platform itself. Communications among the Lattice system 9010 and various components of the operational environment 9000 (e.g., vehicles, sensors, system, networks, and/or the like) are provided via various networks and/or datalinks, and in some cases, includes “mesh” type communications. Examples of such mesh and/or secure communications, and/or other functionality and/or operations of the Lattice system 9010, are described in U.S. Patent Publication No. 2019/0380032, published Dec. 12, 2019, and titled “Lattice Mesh” (the '032 Publication), the entire disclosure of which is hereby made part of this specification as if set forth fully herein and incorporated by reference for all purposes, for all that it contains.

The Lattice system 9010 provides various ways of presenting data and/or enabling user interactions. This includes, for example, various interactive graphical user interfaces provided via user devices such as smartphones 9012 and/or other computing devices 9014. Further examples of sensors, vehicles, and/or systems in the operational environment 9000, and/or operation of the Lattice system 9010, are described in U.S. Patent Publication No. 2020/0167059, published May 28, 2020, and titled “Interactive Virtual Interface” (the '059 Publication), and the '824 Publication, the entire disclosures of each of which are hereby made part of this specification as if set forth fully herein and incorporated by reference for all purposes, for all that they contain.

The Lattice system 9010 can further include various functionality and/or user interfaces as described herein, including tracking various objects and determining options for accomplishing a given task between two or more objects, an evaluator engine that can receive the tracked information and a task to be performed and determine options of potential actions between objects to accomplish the task, and/or the like. In other words, in various implementations the Lattice system 9010 can comprise the system of the present disclosure, and/or the system of the present disclosure can be implemented in, and/or comprise a portion of, the Lattice system 9010.

The control and communications system 9080 includes any existing and/or legacy systems for providing control and communications over, for example, various sensors, systems, and/or vehicles. These control and communications systems 9080 includes various computer systems, user interfaces 9082, hardware and/or devices 9083, and/or the like. The Lattice system 9010 advantageously communicates with the control and communications system 9080 and integrates with the control and communications system 9080 to provide various of the functionality described herein. This includes, for example, communications and coordination with various sensors, systems, and/or vehicles, including to execute missions and achieve operational objectives. These functionalities include providing instructions to various autonomous systems, and enabling various systems to communicate and coordinate with each other.

According to implementations of this disclosure, various aspects of the operational environment 9000 may be considered objects. For example each of the sensor towers 9020, the CUASs 9030, land system(s) 9040, maritime system(s) 9050, and/or the air and/or space system(s) 9060 can be considered objects. Further, each of the objects may comprise or be associated with other objects. For example, each munition available to the CUASs 9030, land system(s) 9040, maritime system(s) 9050, and/or the air and/or space system(s) 9060 can also be considered objects and tracked within the operational environment 9000 accordingly.

Various components of the operational environment 9000, according to various implementations, include evaluation computing systems 102, user devices 120, external devices and/or sensing systems 130, external systems 150, and/or other components and/or functionality of the present disclosure. Various of the CUASs 9030, land systems 9040, maritime systems 9050, air and space systems 9060, and control and communications systems 9080 each optionally include computers. By way of the combination of the computer, each vehicle and/or system advantageously have functionality specific to that vehicle or system, or type of vehicle or system. Such functionality optionally includes, as described herein, receiving sensor and/or operational data, and executing controls to perform tasks and/or seek mission objectives, within the operational environment 9000.

Various components of the operational environment 9000, according to various implementations, include signal transmission and reception systems, object detection systems, and other related components and functionalities. For example, various of the CUASs 9030, land systems 9040, maritime systems 9050, and air and space systems 9060 each optionally include signal and detection management systems. In each case, these systems optionally include respective common and/or similar signal processing boards and application-specific boards. By combining the signal processing board with the application-specific board, each system advantageously performs functions tailored to its specific requirements or type. Such functionality optionally includes, as described herein, detecting objects, receiving sensor or communication data, processing these signals, and transmitting responses or commands to perform tasks and achieve operational objectives within the operational environment 9000.

In various implementations, the system (e.g., one or more aspects of the evaluation computing system 102, user devices 120, external systems 150, other aspects of the operating environment 100, the operational environment 9000 and/or the like) comprise, or are implemented in, a “virtual computing environment”. As used herein, the term “virtual computing environment” should be construed broadly to include, for example, computer-readable program instructions executed by one or more processors (e.g., as described in the example of FIG. 17) to implement one or more aspects of the modules and/or functionality described herein. Further, in this implementation, one or more services/modules/engines and/or the like, of the system are to be understood as comprising one or more rules engines of the virtual computing environment that, in response to inputs received by the virtual computing environment, execute rules and/or other program instructions to modify operation of the virtual computing environment. For example, a request received from the user computing device is to be understood as modifying operation of the virtual computing environment to cause the request access to a resource from the system. Such functionality optionally comprises a modification of the operation of the virtual computing environment in response to inputs and according to various rules. Other functionality implemented by the virtual computing environment (as described throughout this disclosure) optionally further comprises modifications of the operation of the virtual computing environment, for example, the operation of the virtual computing environment optionally changes depending on the information gathered by the system. Initial operation of the virtual computing environment is to be understood as an establishment of the virtual computing environment. In some implementations the virtual computing environment comprises one or more virtual machines, containers, and/or other types of emulations of computing systems or environments. In some implementations the virtual computing environment comprises a hosted computing environment that includes a collection of physical computing resources that are remotely accessible and are rapidly provisionable as needed (commonly referred to as “cloud” computing environment).

Implementing one or more aspects of the system as a virtual computing environment optionally advantageously enables executing different aspects or modules of the system on different computing devices or processors, which increases the scalability of the system. Implementing one or more aspects of the system as a virtual computing environment optionally further advantageously enables sandboxing various aspects, data, or services/modules of the system from one another, which increases security of the system by preventing, e.g., malicious intrusion into the system from spreading. Implementing one or more aspects of the system as a virtual computing environment optionally further advantageously enables parallel execution of various aspects or modules of the system, which increases the scalability of the system. Implementing one or more aspects of the system as a virtual computing environment optionally further advantageously enables rapid provisioning (or de-provisioning) of computing resources to the system, which increases scalability of the system by, e.g., expanding computing resources available to the system or duplicating operation of the system on multiple computing resources. For example, in some cases the system is usable by thousands, hundreds of thousands, or even millions of users simultaneously, and many megabytes, gigabytes, or terabytes (or more) of data are transferred or processed by the system, and scalability of the system enables such operation in an efficient and/or uninterrupted manner.

### Example Implementations of the Evaluation Computing System

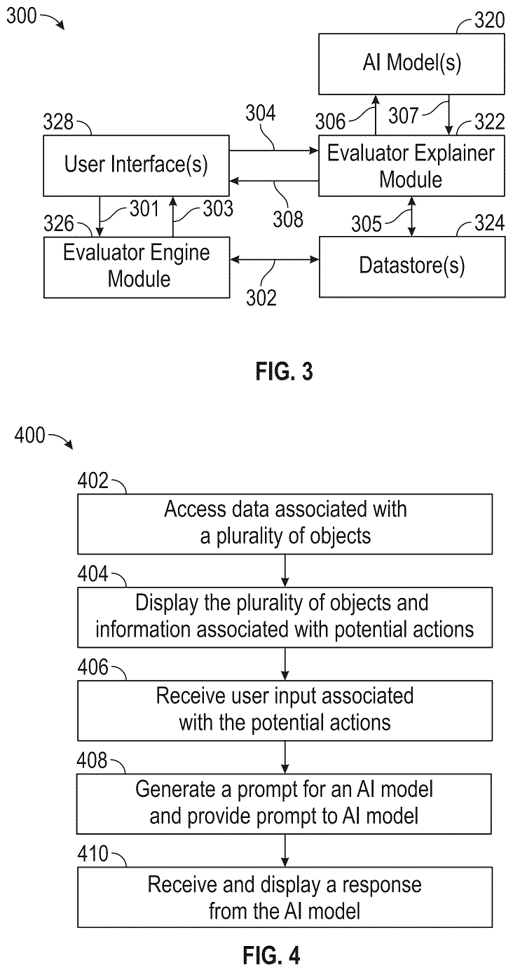

FIG. 3 is a block diagram 300 illustrating operation of an evaluator explainer module 322 in evaluation computing system (e.g., the evaluation computing system 102) in an operating environment (e.g., the operating environment 100). In various implementations, the evaluator explainer module 322 can include all of the features of the evaluator explainer module 106 described above. Similarly, the AI model(s) 320, datastore(s) 324, user interface(s) 328, and evaluator engine module 326 can include all of the features of the AI models 110 (or AI models 152), datastore(s) 114, user interface module 112, and evaluator engine module 104, respectively, described above.

At action 301, a user selects an object on the graphical user interface 328. The graphical user interface 328 can be configured to depict objects within a geographic or other area (e.g., the operational environment 9000 described above). In some embodiments, the selected object can be associated with a task. Examples of tasks include an intelligence, surveillance, and reconnaissance (“ISR”) operation, such as following, monitoring, or surveilling the selected object. Other examples of tasks include damaging or destroying the selected object, traveling to the selected object, or retrieving the selected object. In each of these examples, the object can be considered a “target object” or, in other words, an object that is to be the recipient of an action. In some circumstances, the selected object is a participant in the actions or a sole actor. For illustration, the selected object is considered a target object in the description of block diagram 300. However, some or all of the various operations described below are applicable when the selected object is a mutual or sole actor.

At action 302, the evaluator engine module 326 can retrieve or access information from the datastore(s) 324. The information can include information associated with the current conditions of the geographic area (e.g., object positions, object orientations, information associated with the geographic area, and/or other suitable temporal information) information associated with the objects (e.g., object types, properties, rules, and/or other suitable information), information associated with the relationship between objects (e.g., links between objects, probabilities associated with objects and tasks, and/or other suitable information). The evaluator engine can determine using the retrieved or accessed information options for potential actions to accomplish the task. Each option may describe one or more potential actions between the selected target object and the other objects in the geographic area. For example, in some battlefield contexts, the selected target object may be a vehicle selected to intercept, track, monitor, damage or destroy. In this example, the evaluator engine module 326 can determine using the retrieved or accessed information, options for which of a group of friendly objects can be used to accomplish the task. The evaluator engine module 326 can store the logic used determine the options (e.g., the evaluator engine logic) in the datastore(s) 324.

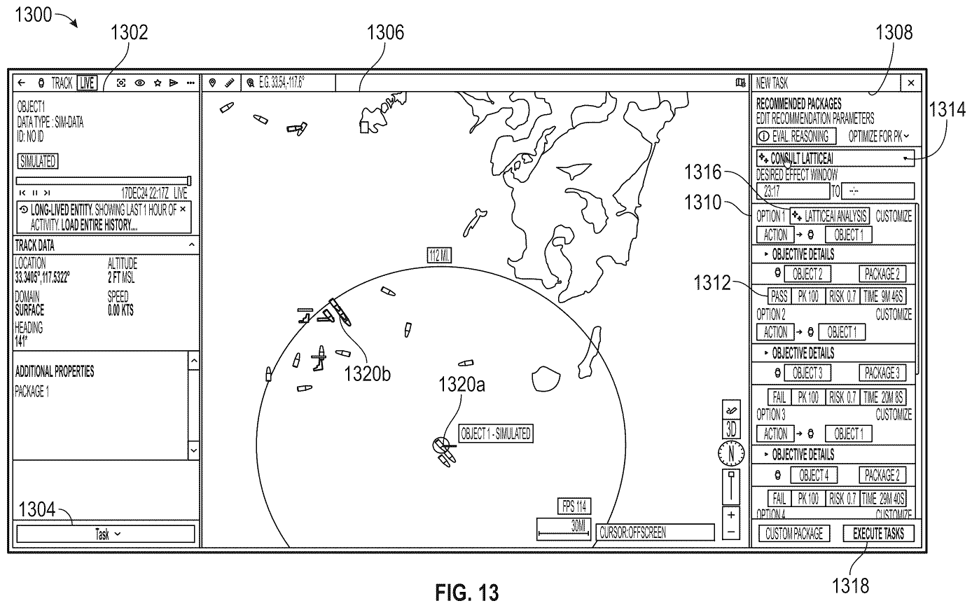

At action 303, the options of potential actions (e.g., options of objects that can perform the task) can be displayed on the graphical user interface 328. At action 304, the user can select on the graphical user interface 328 to initiate the evaluator explainer module (e.g., by selecting an indication to generate a summary of the determined options such as indication 1314 of FIG. 13).

At action 305, the evaluator explainer module 322 can retrieve or access information from the datastore(s) 324. This information can include AI model prompt templates of instructions, the options of potential actions, the evaluator engine logic, and the data accessed or retrieved by the evaluator engine module 326 at action 302. The AI model prompt templates of instructions can include to generate an overview of the one or more potential actions based on the one or more potential actions, the evaluator engine logic, and the accessed data. The evaluator explainer module 322 can generate an AI model prompt based on the retrieved or accessed information.

At action 306 the evaluator explainer module 322 provides the generated prompt to the AI model(s) 320. In various implementations, the AI model(s) 320 includes one or more LLMs. The LLMs can generate an overview of the one or more potential actions using the information provided in the prompt. At action 307, the evaluator explainer module 322 receives the generated overview in a response from the LLM.

At action 308, the overview is displayed on the graphical user interface 328 to a user. One or more of actions 304, 305, 306, 307, and 308 may be repeated to generate subsequent prompts to the AI model(s) 320 for the same options of potential actions determined by the evaluator engine module 326. For example, the evaluator explainer module 322 may retrieve or access information from the datastore(s) 324, generate prompts, provide the prompts to the AI model(s) 320, receive responses from the AI model(s) 320, and display portions of the responses and/or indications of the responses on the graphical user interface 328. In some implementations, actions 305, 306, 307, and 308 are repeated to generate a summary of each option. In one such implementation, after action 308 is performed and the overview is displayed on the graphical user interface 328, the evaluator explainer module 322 automatically repeats actions 305, 306, 307, and 308 and generates the prompts for the individual options, provides the prompts to the AI model(s) 320, receives the responses with the summaries of the individual options and displays (or causes to the display of) an indication of the summaries on the graphical user interface 328.

In various implementations, subsequent iterations of actions 304, 305, 306, 307, and 308 may be in response to a user input to the graphical user interface 328 with an inquiry associated with one or more of the options. For example, the user input can be the text string, “Why did option 1 fail a test?”. The user input can be included in a generated prompt in a similar manner as described above (e.g., using a template) along with the needed contextual information (e.g., the information used to generate options and logic used by the evaluator engine and accessed or retrieved from the datastore(s) 324) and provided to the AI model(s) 320. In various implementations, the AI model(s) 320 or evaluator explainer module 322 may retain contextual information, which may simplify the prompt. The evaluator explainer module 322 may receive a response from the AI model(s) 320 and display the response on the graphical user interface. The evaluator engine module 322 may receive additional user input and repeat the process described above to generate AI model prompts and receive and display AI model responses. In various implementations, the user input and the AI model responses may be displayed together on the graphical user interface 328.

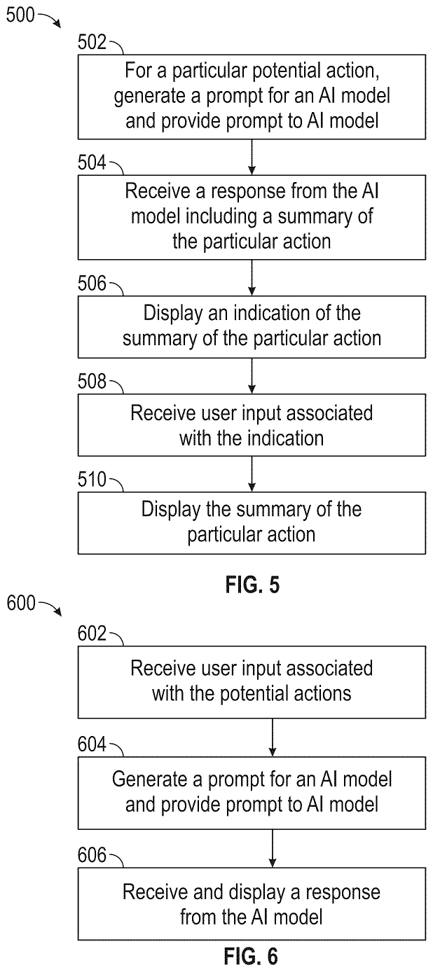

FIGS. 4 and 5 illustrate example flows or methods of generating overviews of potential actions between objects and generating summaries of particular objects, according to various implementations. Although FIGS. 4 and 5 illustrate examples of generating overviews of potential actions between objects and generating summaries of particular objects, other methods are possible and described elsewhere herein. Further, in various implementations various blocks of the flows or methods may be rearranged, optional, and/or omitted, and/or additional blocks may be added. The blocks illustrated schematically in FIG. 4 and FIG. 5 will be described with reference to certain hardware components of the present disclosure. However, it will be understood that the hardware components of FIG. 4 and FIG. 5 and/or individual components or subsets thereof may equally be implemented in conjunction with other hardware components, software components, and/or systems without departing from the scope of the present disclosure. According to various implementations, FIGS. 4 and 5 may be computer-implemented.

FIG. 4 illustrates an example process 400 of generating overviews of potential actions between objects. FIG. 5 illustrates an example process 500 of generating summaries of particular objects. In various implementations, the process 500 illustrated in FIG. 5 automatically begins at the conclusion of the process 400 illustrated in FIG. 4. In other implementations, process 500 does not begin after the conclusion of process 400 until the system is instructed to proceed (e.g., via a user input). In other implementations, process 400 and process 500 may be executed in isolation. For example, process 500 may be executed without process 400 occurring priorly or subsequently, and vice versa.

Referring to process 400 of FIG. 4, at block 402, the system accesses data associated with a plurality of objects. The data may include a task to be performed, one or more options of potential actions between two or more objects, logic (e.g., evaluator engine logic) associated with a determination of the one or more options, information associated with the one or more potential actions (e.g., information used in the determination of the one or more options) and/or other suitable information described herein.

At block 404, the system can display (or cause to display) the plurality of objects and some, or all, of the information associated with the one or more potential actions on a graphical user interface. In various implementations, the graphical user interface can include user preferences for the display of information (e.g., preferred units of measurements, time zones, display languages, or other suitable display preferences). At block. 406 the system can receive user input associated with the potential actions. In various implementations, the user input can be a selection of an indication to generate a summary of the potential actions.

At block 408, the system generates a prompt for an AI model and provides the prompt to the AI model. The prompt can include the one or more options of potential actions, information used in the determination of the one or more options (e.g., at least a portion of the accessed information), and the evaluator engine logic in a prompt to an AI model. In various implementations, the system may generate a prompt for the AI model by populating a template prompt with the information used in the determination of the one or more options, and evaluator engine logic. The template prompt may also include instructions (e.g., static descriptions or instructions) to the AI model on what to do with the provided information. The instructions can include instructions for the AI model to generate an overview of the one or more potential actions based on the one or more potential actions, the evaluator engine logic, and the information used in the determination of the one or more options (e.g., at least a portion of the accessed information).

At block 410, the system receives a response and displays, at least of a portion of the response on the graphical user interface. The response can include the overview of the one or more potential actions. In various implementations, rather than displaying the overview on the graphical user interface, the system displays an indication of the overview. In these implementations, the system can display the overview on the graphical user interface in response to a user input (e.g., a user selecting the displayed indication or placing a cursor on the displayed indication).

Referring to process 500 of FIG. 5, at block 502, the system generates, for a particular potential action of one or more options of potential actions (such as those described above with reference to FIG. 4), a prompt for an AI model. The prompt can include the particular potential action to summarize, associated evaluator engine logic, and relevant information used by the evaluator engine to determine the particular potential action, and instructions to generate a summary of the particular potential action. The system can generate the prompt by using a prompt template, such as those described herein. The system can provide the prompt to the AI model.

At block 504 the system can receive a response from the AI model including a summary of the particular action. At block 506 the system can display an indication of the summary of the particular action. The indication can be displayed in association with the particular option (e.g., indication 1316 illustrated in FIG. 13 is displayed in association with the particular option display 1310) on a graphical user interface.

At block 508, the system receives a user input associated with the indication of the summary of the particular action. For example, the system can receive, from the graphical user interface, a user input associated with the indication (e.g., a user selecting the indication or a user placing a cursor over the indication). At block 510, the system displays the summary of the particular action in response to the user input.

In various implementations, process 400 and process 500 are performed automatically in response to a single user input (e.g., the user input received at block 406). In some implementations, rather than providing separate prompts, the system can generate a prompt that includes the above described information and instructions to generate and overview of the options and a summary of each individual option in a single prompt.

FIG. 6 illustrates an example flow or method of generating follow up responses from an AI model based on potential actions between objects, according to various implementations. Although FIG. 6 illustrates an example process 600 of generating follow up responses from an AI model based on potential actions between objects, other methods are possible and described elsewhere herein. Further, in various implementations various blocks of the flows or methods may be rearranged, optional, and/or omitted, and/or additional blocks may be added. The blocks illustrated schematically in FIG. 6 will be described with reference to certain hardware components of the present disclosure. However, it will be understood that the hardware components of FIG. 6 and/or individual components or subsets thereof may equally be implemented in conjunction with other hardware components, software components, and/or systems without departing from the scope of the present disclosure. According to various implementations, FIG. 6 may be computer-implemented.

In various implementations, process 600 begins after process 400 of FIG. 4 and/or process 500 of FIG. 5 concludes. However, implementations of process 600 may occur in a different order or separately from process 400 of FIG. 4 and/or process 500 of FIG. 5. At block 602, the system receives user input associated with potential actions. The potential actions can be the same potential actions discussed with respect to FIGS. 4 and 5. The user input can include a string of text.

As described above, the user may desire further information regarding the generated options (e.g., further information that what was generated and presented from processes 400 and 500). The system may generate, automatically or in response to a user input, and display a field for the user to input questions associated with the options. The user input can be in plain language (e.g., a plain English question). For example, the user input can be the text string, “Why did option 1 fail a test?”.

At block 604, the system can generate a prompt that includes the user input in a similar manner as described above (e.g., using a template) along with the needed contextual information (e.g., the information used to generate options and logic used by the evaluator engine) and provide the prompt to an AI model. In various implementations, the AI model or system may retain contextual information, which may simplify the prompt.

AT block 606, the system may receive and display an AI model response on the graphical user interface. The system may receive additional user input and repeat the process 600 to generate AI model prompts and receive and display AI model responses. In various implementations, the user input and the AI model responses may be displayed together on the graphical user interface.

According to various implementations of process 400, process 500, and/or process 600, the system may utilize marking or tagging scheme to preserve the user preferences described above. In various implementations, the instructions provided in the prompts to the AI model can have instructions for marking or tagging information the AI model generates, such that, when the system receives and displays that information, the user preferences are maintained. In a nonlimiting example, the system may include instructions for the AI model to output in JSON format. Relevant portions (e.g., portions that can be displayed differently based on user preference) of the JSON format can be associated with HTML tags in marked down strings. When parsing the marked down strings, the system can identify the HTML tags and display the information according to the user preference.

The various AI model responses may also include answers in more than one language. In various implementations of process 400, process 500, and/or process 600, the AI model responses of different languages may be determined separately, meaning that the AI model can generate the response in a first language and a response in a second language, using the same information, rather than generating a response in the first language and translating the response to the second language. In various implementations, the languages may be translated.

Further, the AI models used in process 400, process 500, and process 600 may be the same AI models, different AI models, or some combination of the two (e.g., one AI model may be shared by two, or all three, of process 400, process 500, or process 600).

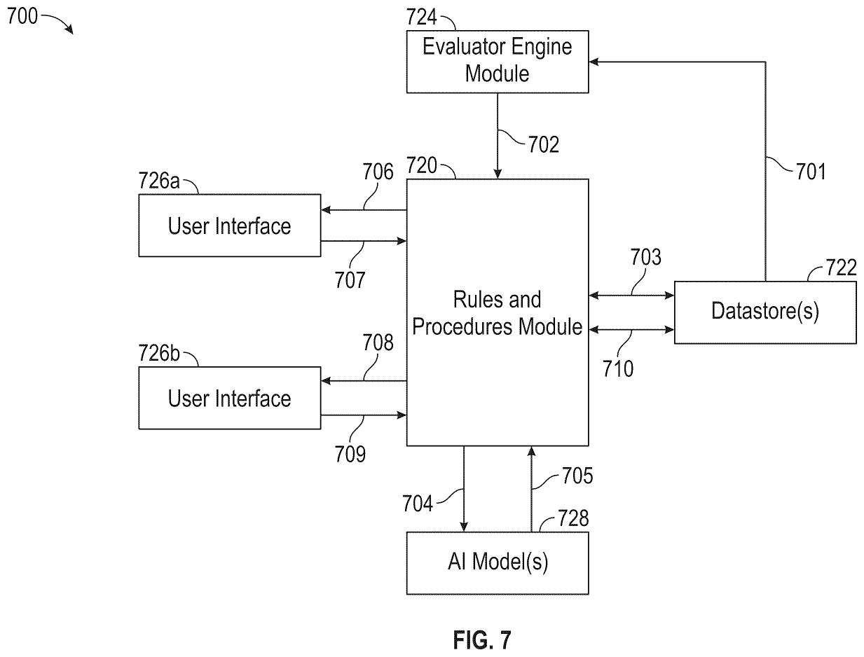

FIG. 7 is a block diagram 700 illustrating operation of a rules and procedures module 720 in evaluation computing system (e.g., the evaluation computing system 102) in an operating environment (e.g., the operating environment 100). In various implementations, the rules and procedures module 720 can include all of the features of the rules and procedures module 108 described above. Similarly, the AI model(s) 728, datastore(s) 722, user interfaces 726a, 726b, and evaluator engine module 724 can include all of the features of the AI models 110 (or AI models 152), datastore(s) 114, user interface module 112, and evaluator engine module 104, respectively, described above.

At action 701, information is transmitted to the evaluator engine module 724 and the evaluator engine module 724 model determines one or more potential actions between objects from the information. At action 702, a rules and procedures module 720 access information indicating potential action between objects from the evaluator engine module 724. In various implementations, rather than accessing the information from the evaluator engine module 724, the information can be accessed from another source, such as the datastore(s) 722 or the information can be received from a user via a graphical user interface.

As noted above, the rules and procedures module 720 can use the accessed information and a set of rules and procedures to determine whether the potential actions comply with the set of rules and procedures (e.g., by using the actions 703 to 706 described below). In various implementations, the rules and procedures module 720 can automatically begin the determination (e.g., continue to action 703). In other implementations, the rules and procedures module can begin the determination based on user input (e.g., a user selecting a potential action on a graphical user interface or a user entering a potential action for the system to check on the graphical user interface). The set of rules and procedures can include a relatively large amount of information. As such, the set of rules and procedures may be too large to be referenced in some situations. For example, the set of rules and procedures may be too large to provide to an LLM in a prompt (e.g., the set of rules and procedures exceeds a character limit and/or would take an impractically long time to process).

At action 703, the 720 retrieves any additional information from the datastore(s) 722 (e.g., a set of rules and procedures, LLM prompt templates, and/or other additional information), determines one or more logical blocks from the set of rules and procedures, and generates a prompt for an LLM. In various implementations, the rules and procedures module 720 can determine the logical blocks by using a similarity search on the set of rules and procedures. The similarity search can include searching the set of rules and procedures for words or phrases associated with the potential actions and/or the objects. The logical blocks can be documents of set of rules and procedures where the words or phrases occur, pages of the set rules and procedures where the words or phrases occur, sections of the set rules and procedures where the words or phrases occur, sentences of the set rules and procedures where the words or phrases occur, and/or other partitions of the set of rules and procedures associated with the words or phrases. In various implementations, the rules and procedures module 720 can determine the logical blocks using other techniques (e.g., by using metadata to associate the potential actions and/or objects to portions of the set of rules and procedures).

In various implementations, the rules and procedures module can generate the prompt for the LLM that includes the potential actions, the accessed information, the determined logical blocks from the set of rules and procedures, and instructions for the LLM to generate indications of whether the each of the potential actions complies with the provided rules and procedures. In various implementations, the prompt can include other information and/or omit some of the above mentioned information. The rules and procedures module 720 can generate the prompt in a similar manner as the evaluator explainer module (e.g., using a template prompt with static and dynamic portions). At action 704, the rules and procedures module 720 provides the prompt to an AI model 728, such as an LLM.

At action 705, the rules and procedures module 720 can receive a response from the AI model 728 with the indications of whether each of the potential actions complies with the set of rules and procedures. At action 706, the rules and procedures module 720 can cause a graphical user interface 726a to display each of the potential actions along with an associated indication of whether the potential action complies with the set of rules and procedures. In various implementations, the operations of the rules and procedures module 720 may conclude at action 706.

In some instances, a user may wish to perform a potential action indicated by the rules and procedures module as not complying the set of rules and procedures and/or may otherwise wish to receive authorization for the potential action. According to various implementations, a user may select (e.g., by using graphical user interface 726a) a particular potential action associated with an indication that the particular action does not comply with the set of rules and procedures. At action 707, the rules and procedures module 720 can receive the user input.

At action 708, the rules and procedures module 720 can send to and/or cause the particular potential action to be displayed on graphical interface 726b, which may be associated with a user with authority to authorize the potential action. In various implementations, the particular action is displayed to the user with authority to authorize the potential action on a different graphical user interface (e.g., graphical user interface 726b) than the user wishing to perform the potential action (e.g., graphical user interface 726a). For example, the user with authority to authorize the potential action may have access to a graphical user interface 726b that includes the capability to provide authority to perform actions (e.g., using one or more buttons, fields, and/or the like).

At action 709, the rules and procedures module can receive an input from the separate graphical user interface 726b with an authorization from the user with authority permitting (or authorizing) the particular action to be performed. The rules and procedures module can generate an alert and display (e.g., on the graphical user interface 726a) the alert to the user wishing to perform the potential action that the potential action has been authorized.

At action 710, the authorization can be stored in the datastore(s) 722. In various implementations, when the authorization is stored in the datastore(s) 722, actions 701-706 are automatically reperformed to reflect the authorization and any other changes in circumstances (e.g., changes in the operating environment).

In some implementations, some, or all of, actions 708-710 may alternatively or additionally represent a different set of actions. For instance, some, or all of the information used and generated by the rules and procedures module 720 may be tracked and/or recorded in a log (e.g., in datastore(s) 722). For example, the rules and procedures module may track the accessed information, the potential actions, the logical blocks, the generated prompts, the responses received from an AI model, requests for authorization of potential actions, authorizations, and/or other information used or generated by the rules and procedures module or users may be tracked and/or recorded in a log.

Accordingly, at alternate action 708, the log, or a portion of the log, can be presented to a user (e.g., a human in the loop) via another graphical user interface 726b (e.g., a third graphical user interface that is different than the one used in the previously described action 708). At action alternate 709, the rules and procedures module can receive input from the user verifying or correcting one or more items of the log. For example, the user may verify or correct the determined logical blocks, the indications whether a potential action complies with the set of rules and procedures, the set of rules and procedures, authorizations to perform particular potential actions, and/or other information in the log.

At alternate action 710, the rules and procedures module 720 can record the verifications and corrections in the datastore(s) 722. In various implementations, when the verifications and corrections are recorded in the datastore(s) 722, actions 701-706 are automatically reperformed to reflect the verifications and corrections and any other changes in circumstances (e.g., changes in the operating environment).

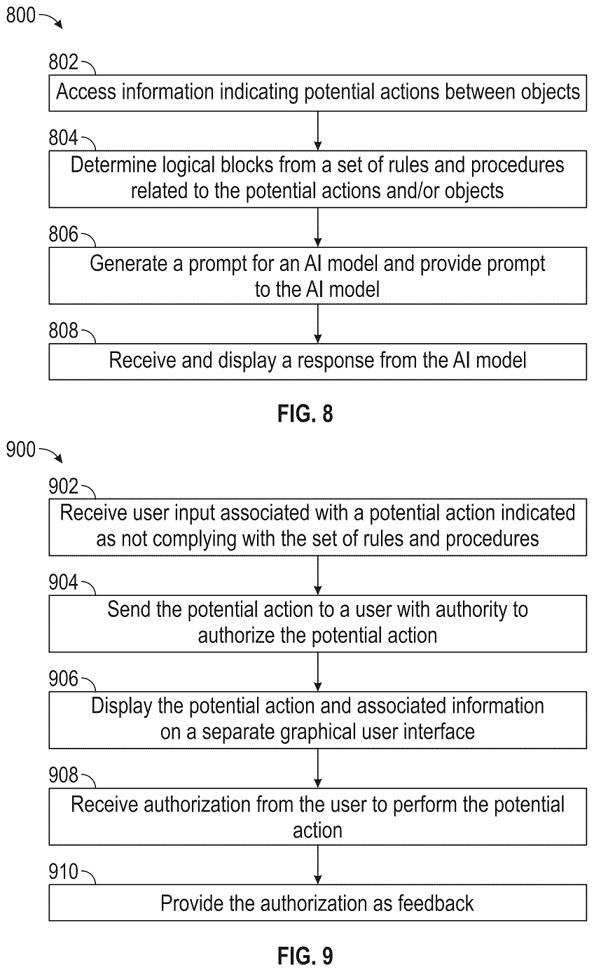

FIGS. 8-10 illustrate example flows or methods of generating indications that potential actions between objects comply with a set of rules and procedures, according to various implementations. Although FIGS. 8-10 illustrate examples of generating indications that potential actions between objects comply with a set of rules and procedures, other methods are possible and described elsewhere herein. Further, in various implementations various blocks of the flows or methods may be rearranged, optional, and/or omitted, and/or additional blocks may be added. The blocks illustrated schematically in FIGS. 8-10 are described with reference to certain hardware components of the present disclosure. However, it will be understood that the hardware components of FIGS. 8-10 and/or individual components or subsets thereof may equally be implemented in conjunction with other hardware components, software components, and/or systems without departing from the scope of the present disclosure. According to various implementations, FIGS. 8-10 may be computer-implemented.

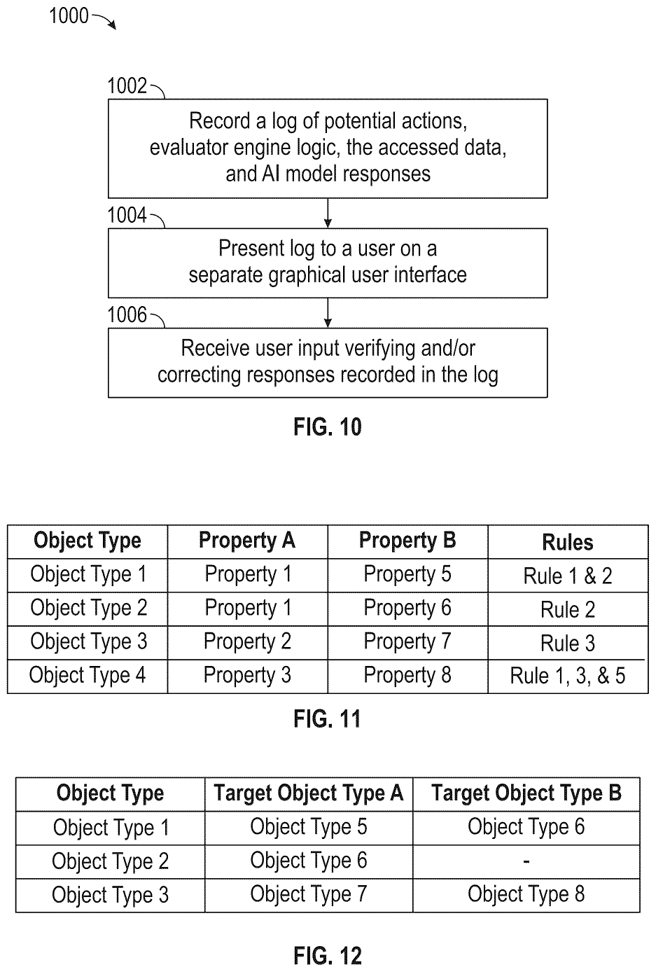

FIG. 8 illustrates an example process 800 of generating indications that potential actions comply with a set of rules and procedures. FIG. 9 illustrates an example process 900 of receiving authorization for a potential action and regenerating the indications that potential actions comply with a set of rules and procedures. FIG. 10 illustrates and example process 1000 of receiving verifications and corrections and regenerating the indications that potential actions comply with a set of rules and procedures.

Referring to FIG. 8, at block 802, the system accesses information indicating potential actions between objects. The information can be generated or determined by the system (e.g., by using an evaluation engine), entered by a user (e.g., by one or more user inputs) and/or otherwise generated or determined. The system can use the accessed information and a set of rules and procedures to determine whether potential actions comply with the set of rules and procedures (e.g., as described below in blocks 804-808). The set of rules and procedures can include a relatively large amount of information. As such, the set of rules and procedures may be too large to be referenced in some situations. For example, the set of rules and procedures may be too large to provide to an AI model in a prompt (e.g., the set of rules and procedures exceeds a character limit and/or would take an impractically long time to process).

At block 804, the system determines logical blocks from a set of rules and procedures related to the potential actions and/or objects. In various implementations, the system can determine the logical blocks by using a similarity search on the set of rules and procedures. The similarity search can include searching the set of rules and procedures for words or phrases associated with the potential actions and/or the objects. The logical blocks can be documents of set of rules and procedures where the words or phrases occur, pages of the set rules and procedures where the words or phrases occur, sections of the set rules and procedures where the words or phrases occur, sentences of the set rules and procedures where the words or phrases occur, and/or other partitions of the set of rules and procedures associated with the words or phrases. In various implementations, the system can determine the logical blocks by using other techniques. For example, using metadata to associate the potential actions and/or objects to portions of the set of rules and procedures.

At block 806, the system generates a prompt for an AI model and provides the prompt to the AI model. The system can use the determined logical blocks of the set of rules and procedures in the prompt. In various implementations, the system can generate a prompt for an AI model that includes the potential actions, the accessed information, the determined logical blocks from the set of rules and procedures, and instructions for the AI model to generate indications of whether the each of the potential actions complies with the provided rules and procedures. In various implementations, the prompt can include other information and/or omit some of the above mentioned information. The system can generate the prompt in a similar manner as the evaluator explainer (e.g., using a template prompt with static and dynamic portions).

At block 808, the system receives and displays a response from the AI model on a graphical user interface. The response can include the indications of whether each of the potential actions complies with the set of rules and procedures. The system can cause the graphical user interface to display each of the potential actions along with an associated indication of whether the potential action complies with the set of rules and procedures.

Referring to FIG. 9, process 900 may continue at the conclusion of process 800 (e.g., after block 808 concludes). However, process 900 can also be used in other contexts, such as at the conclusion of process 1000 described below or in isolation from either process 800 or process 1000.

At block 902, the system receives user input associated with a potential action indicated as not complying with the set of rules and procedures. In some instances, a user may wish to perform a potential action indicated by the rules and procedures module as not complying the set of rules and procedures and/or may otherwise wish to receive authorization for the potential action. According to various implementations, a user may select a particular potential action associated with an indication that the particular action does not comply with the set of rules and procedures. The system can receive the user input.

At block 904, the system sends the potential action to a user with authority to authorize the potential action. For example, the system may send the potential action up a chain of command. At block 906, the system displays the potential action and associated information on a separate graphical user interface. The potential action can be displayed to the user with authority to authorize the potential action on a different user interface than was used by the user wishing to perform the potential action. For example, the user with authority to authorize the potential action may have access to a graphical user interface that includes the capability to provide authority to perform actions (e.g., via one or more buttons, fields, and/or the like, of the graphical user interface).

At block 908, the system receives authorization for the user to perform the potential action. The system can receive the input from the separate graphical user interface with an authorization from the user with authority permitting (or authorizing) the particular action to be performed. The system can generate an alert and display (e.g., on a graphical user interface) the alert to the user wishing to perform the potential action that the potential action has been authorized.

At block 910, the system may provide the authorization as feedback. For example, when the authorization is received the system may perform one or more of the operations described herein with the authorization as feedback. For instance, process 800 may be performed, or reperformed, with the authorization accounted for, which may in turn effect the potential options, the objects, the logical blocks, the generated prompt, and/or the indications.

Referring to FIG. 10, process 1000 may continue at the conclusion of process 800 (e.g., after block 808 concludes). However, process 1000 can also be used in other contexts, such as at the conclusion of process 900 described below or in isolation from either process 800 or process 900.

At block 1002, the system records a log of potential actions, evaluator engine logic, the accessed data, AI model responses, and/or other information. For example, some, or all of the information used and generated by the system in processes 800 and 900 may be tracked and/or recorded in a log.

At block 1004, the system presents the log to a user on a separate graphical user interface. For example, the system may present the log to a JAG. At block 1006, the system receives user input verifying and/or correcting responses (or other information) recorded in the log. For example, the user may verify or correct determined logical blocks, indications of whether a potential action complies with the set of rules and procedures, a set of rules and procedures, authorizations to perform particular potential actions, and/or other information in the log. The system can record the verifications and corrections. In various implementations, the system may then reperform any of the above described operations (e.g., processes 800 or 900) in light of the recorded verifications and corrections. For example, the system may redetermine the potential actions, the objects, and the logical blocks and regenerate a prompt to the LLM based on the recorded verifications and corrections.

### Example Information Associated With Objects

FIG. 11 and FIG. 12 illustrates examples of information that can be used by an evaluator engine module to generate the one or more potential actions and/or used by an evaluator explainer engine to generate prompts for AI models, as described herein. FIG. 11 is an example table of Object Types and associated properties and rules. As illustrated in FIG. 11, each object type has two associated properties and a number of rules associated with the object type. However, it should be understood that each object type may have more (or fewer) properties and rules.

The object type as used in FIG. 11 and FIG. 12 can refer to a class or subclass of objects that share common properties and/or rules. As an illustrative example, when considering cars as objects, an object type could refer to all road passenger vehicles, all sports utility vehicles (SUVs), all SUVs of a particular manufacturer, and/or all SUVs of a particular make and model. For this to be true, each of these classes or subclasses would have to have at least one common property or rule.

Continuing the example of car objects, Object Type 1 of FIG. 11 may be electric vehicles and Object Type 2 may be combustion engine vehicles. Both the electric vehicles and the combustion engine vehicles can have some shared properties (e.g., Property 1 may be that the vehicle type is legally able to drive on a highway). However, the total range of the two vehicles may be different (e.g., Property 5 and Property 6 may indicate different total ranges of travel. Further, the two vehicles may have shared and different rules (e.g., Rule 2 may be that the vehicles cannot travel farther than their max range without refueling (or recharging) and Rule 1 may define a minimum amount of time to charge.

Returning to a battlefield example implementation, FIG. 11 an illustrate properties and rules associated with different munitions and vehicles. For example, Object Type 1 and Object Type 2 may be different munitions carried on various aircraft. In this example, Property 1 can be an associated range of the two munitions and Properties 5 and 6 can be associated velocities. Rule 2 may stipulate that target objects have to be less than the range and Rule 1 may stipulate a tracking requirement. Object Type 3 may be a type of aircraft that carries the Object Type 2 munitions, which can be identified in a property of Object Type 3 (e.g., Property 7). From this example, it can be seen that not only can objects be compared, but also associated (e.g., Object Type 3 carries Object Type 2).

FIG. 12 illustrates an example table linking object types. Each object type can be linked with multiple target object types (e.g., a object selected by a user). Continuing the previous example, the table of FIG. 12 may identify that Object Type 3 (a type of aircraft) is effective against target objects of Object Type 7. One reason for this may be that Object Type 2 munitions carried by the Object Type 3 is effective against target objects of Object Type 7. Accordingly, one determination an evaluator engine may make for an option of potential actions toward a target object of Object Type 7 is to locate Object Type 3 aircraft within the range defined by property 1. In doing so, the evaluator engine may track the information used (e.g., the table of FIG. 11 and the table of FIG. 12), the rules examined (e.g., Rule 2), and links between object types (e.g., Object Type 2 to Object Type 3 and Object Type 3 to Object Type 7). The tables illustrated in FIG. 11 and FIG. 12 represent one way to provide data that can be used, in association with current data within an operating environment, to determine one or more potential actions between two or more objects and are provided for illustrative purposes only. Other ways of storing, presenting, associating, and/or otherwise handling information associated with the objects and/or operating environments may be used.

### Example Graphical User Interfaces

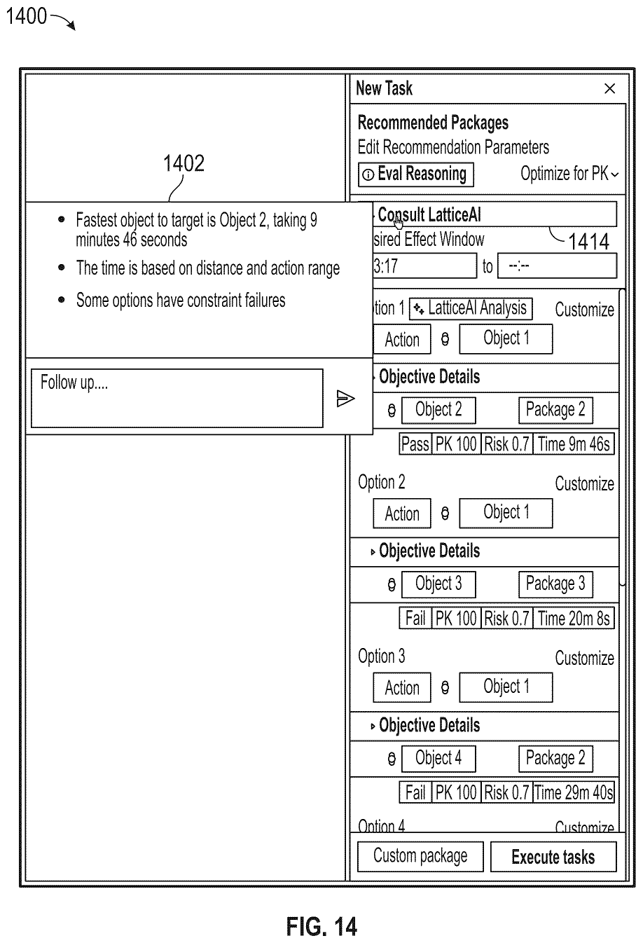

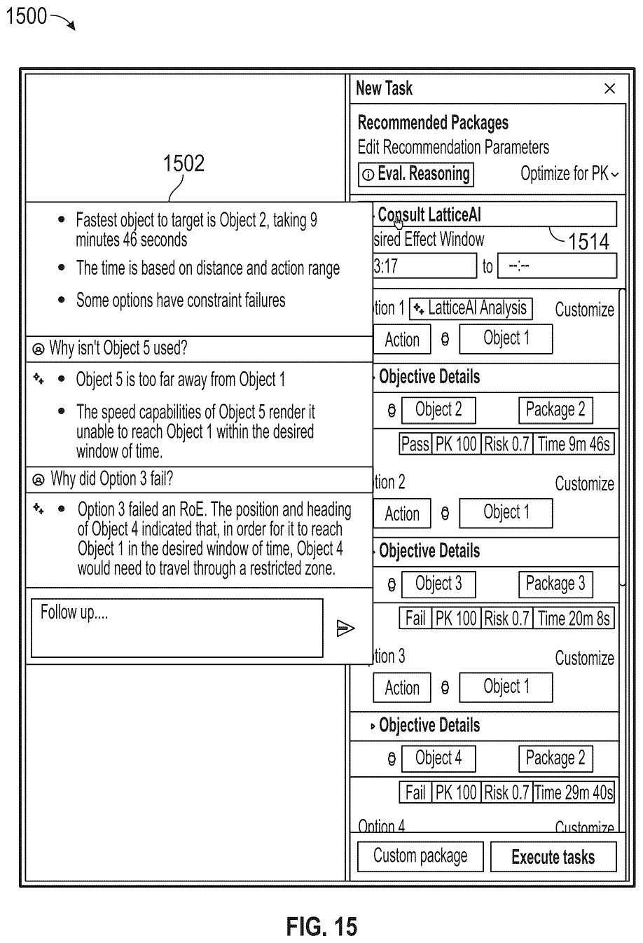

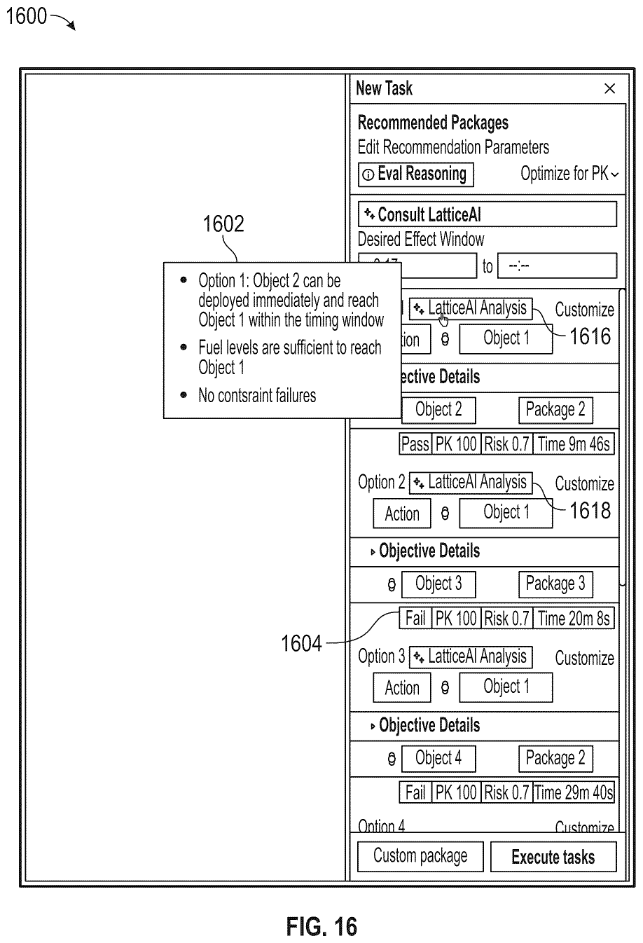

FIG. 13, FIG. 14, FIG. 15, and FIG. 16 illustrate example graphical user interfaces according to various embodiments. As described above, the graphical user interfaces can be used by the system to display information, such objects in an operating environment, a task, one or more options of potential actions between the objects, overviews and summaries of options of potential actions associated with a task, and/or responses to user inquiries. Further, the one or more graphical user interfaces can be used to received user inputs, such as a user input to initialize an evaluator explainer, a user input with questions regarding the options of potential actions, and/or other user input. In various embodiments the graphical user interfaces illustrated in FIG. 13, FIG. 14, FIG. 15, and FIG. 16 represent example implementations of the various graphical user interfaces described herein, such as the user interface(s) 328, user interface 726a, user interface 726b, and/or other graphical user interface described herein.

FIG. 13 illustrates an example graphical user interface 1300 that perform some, or all, of the above identified functions. Graphical user interface 1300 includes a selected object display portion 1302, and task selection button 1304, a map viewer 1306 with objects displayed (e.g., selected object 1320a and first option object 1320b), an options display portion 1308, a overview indicator 1314, a particular option display 1310, an option summary indicator 1316, and a execute task button 1318.

The selected object display portion 1302 can information associated with a selected object. For example, the selected object 1320a is illustrated as selected in graphical user interface 1300. As such, the selected object display portion 1302 includes information associated with the selected object 1320a, including track data with tracked location, altitude, speed and heading. The selected object display portion 1302 can also display know properties of the selected object (e.g., that selected object 1320a contains package 1). The map viewer 1306 can illustrate the tracked objects and with positions and headings. The map viewer 1306 can also illustrate other information, such as a range of a selected object. In various implementations, a user can select one of the objects on the map viewer 1306.

As described above, the system may generate one or more potential actions between the objects to accomplish a task. In various implementations, the task may be selected using the task selection button 1304. The generated potential actions can be displayed in the options display portion 1308. For example, the particular option display 1310 can display one option for a potential action. Prior to generating an overview of the potential actions, a user may select the overview indicator 1314 to initiate the process (e.g., as described at block 406 of process 400). According to various implementations, when a user selects the overview indicator 1314 the system generates the overview of the options of potential actions by generating one or more prompts for AI models, providing them to the AI models, and receiving and displaying one or more responses from the AI models.

FIG. 14 illustrates an example graphical user interface 1400 after the overview of the options of potential actions has been generated. As illustrated in FIG. 14, after the overview of the potential actions, a user may view the overview by selecting (e.g., by hovering a cursor over an overview indicator 1414 (which can correspond to the overview indicator 1314 of FIG. 13). When the overview indicator 1414 is selected, an overview display window 1402 can appear and display the generated overview. The overview display window 1402 may also include a field for a user to enter (e.g., type) follow up questions regarding the options of potential actions.

FIG. 15 illustrates an example graphical user interface 1500, illustrating example responses to such user enter questions. Like graphical user interface 1400, a user has selected an overview indicator 1514 and a overview display window 1502 has been overlayed on the graphical user interface 1500. As illustrated, a user has entered two inquiries: “Why isn't Object 5 used?” and “Why did Option 3 fail?” The overview display window 1502 includes the overview of potential actions, the user inquires, and responses generated by an AI model based on the user inquiries and the provided information described herein. As shown, the overview display window 1502 can provide the information in one place (e.g., as a continuous thread).

FIG. 16 illustrates an example graphical user interface 1600, illustrating an example particular option summary display window 1602 and multiple generated option summary indicators 1316, 1618. The system can display the generate option summary indicators 1616, 1618 as the system receives the respective particular option summaries from the AI models. For example, the illustrated examples of FIGS. 13-16, the particular option summary of “Option 1” completes and an indicator of the associated particular option summary (e.g., option summary indicator 1316) is displayed before indicators of other options.

When an option summary indicator 1616, 1618 is selected (e.g., by placing a cursor over the option summary indicator 1616, 1618) the summary of the particular option is displayed in the summary display window 1602, which can be overlayed onto the graphical user interface 1600. The summary of the particular can provide a user with context to formulate further inquiries and/or select an option to execute.

Returning to FIG. 13, when a user determines an option of potential actions to execute, the user can select the desired option and select the execute task button 1318. In various implementations, the execute task button 1318 can cause the potential action to occur (or attempt to occur). For example, the object may be configured to automatically act when the execute task button 1318 is selected. In other implementations, (such as implementation where a user does not have authority to execute the task) the execute task button 1318 may be omitted or replaced by a different button (e.g., a button to recommend a course of action to a user having authority to review).

According to various implementations, the various graphical user interfaces of the system (e.g., graphical user interfaces 1300, 1400, 1500, and 1600) can include indications of whether an option of potential actions passes or fails one or more tests. For example, graphical user interface 1300 includes a pass indication 1312 associated with particular option display 1310. As another example, graphical user interface 1600 includes a fail indication 1604 associated with an “Option 2.” The indications can be associated with more than one test, which can be performed by different components of the system described herein, such as the evaluator engine module 104, evaluator explainer module 106, or rules and procedures module 108 illustrated in FIG. 1.

In various implementations, the tests can be associated with the determination of the option of particular actions. For example, one of the objects associated with the option may be associated with insufficient track quality (e.g., the position or other attribute of the object may not be known with a needed level of precision to perform the potential action.

In various implementations, the tests can be associated with a set of rules and procedures, such as those discussed with reference to FIGS. 1 and 7-10. In these implementations, the indications can be whether the particular option complies with the set of rules and procedures (e.g., the pass indication 1312) or does not comply with the set of rules and procedures (e.g., the fail indication 1604). In various implementations, a user may select an indication an option does not comply with the set of rules and procedures (e.g., the fail indication 1604) and request authorization of the associated potential actions, such as is described above with reference to process 800 of FIG. 8.

### Example Computing System

In various implementations, the system (e.g., one or more aspects of the evaluation computing system 102, external system 150, user devices 120, other aspects of the operating environment 100, and/or the like) may comprise, or be implemented in, a “virtual computing environment”. As used herein, the term “virtual computing environment” should be construed broadly to include, for example, computer-readable program instructions executed by one or more processors (e.g., as described in the example of FIG. 17) to implement one or more aspects of the modules and/or functionality described herein. Further, in this implementation, one or more services/modules/engines and/or the like, of the system may be understood as comprising one or more rules engines of the virtual computing environment that, in response to inputs received by the virtual computing environment, execute rules and/or other program instructions to modify operation of the virtual computing environment. For example, a request received from the user computing device may be understood as modifying operation of the virtual computing environment to cause the request access to a resource from the system. Such functionality may comprise a modification of the operation of the virtual computing environment in response to inputs and according to various rules. Other functionality implemented by the virtual computing environment (as described throughout this disclosure) may further comprise modifications of the operation of the virtual computing environment, for example, the operation of the virtual computing environment may change depending on the information gathered by the system. Initial operation of the virtual computing environment may be understood as an establishment of the virtual computing environment. In various implementations the virtual computing environment may comprise one or more virtual machines, containers, and/or other types of emulations of computing systems or environments. In various implementations the virtual computing environment may comprise a hosted computing environment that includes a collection of physical computing resources that may be remotely accessible and may be rapidly provisioned as needed (commonly referred to as “cloud” computing environment).

Implementing one or more aspects of the system as a virtual computing environment may advantageously enable executing different aspects or modules of the system on different computing devices or processors, which may increase the scalability of the system. Implementing one or more aspects of the system as a virtual computing environment may further advantageously enable sandboxing various aspects, data, or services/modules of the system from one another, which may increase security of the system by preventing, e.g., malicious intrusion into the system from spreading. Implementing one or more aspects of the system as a virtual computing environment may further advantageously enable parallel execution of various aspects or modules of the system, which may increase the scalability of the system. Implementing one or more aspects of the system as a virtual computing environment may further advantageously enable rapid provisioning (or de-provisioning) of computing resources to the system, which may increase scalability of the system by, e.g., expanding computing resources available to the system or duplicating operation of the system on multiple computing resources. For example, the system may be used by thousands, hundreds of thousands, or even millions of users simultaneously, and many megabytes, gigabytes, or terabytes (or more) of data may be transferred or processed by the system, and scalability of the system may enable such operation in an efficient and/or uninterrupted manner.

Various implementations of the present disclosure may be a system, a method, and/or a computer program product at any possible technical detail level of integration. The computer program product may include a computer-readable storage medium (or mediums) having computer-readable program instructions thereon for causing a processor to carry out aspects of the present disclosure.

For example, the functionality described herein may be performed as software instructions are executed by, and/or in response to software instructions being executed by, one or more hardware processors and/or any other suitable computing devices. The software instructions and/or other executable code may be read from a computer-readable storage medium (or mediums). Computer-readable storage mediums may also be referred to herein as computer-readable storage or computer-readable storage devices.

The computer-readable storage medium can be a tangible device that can retain and store data and/or instructions for use by an instruction execution device. The computer-readable storage medium may be, for example, but is not limited to, an electronic storage device (including any volatile and/or non-volatile electronic storage devices), a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a solid-state drive, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers, and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions (as also referred to herein as, for example, “code,” “instructions,” “module,” “application,” “software application,” and/or the like) for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, Java, C++, or the like, and procedural programming languages, such as the “C” programming language or similar programming languages. Computer-readable program instructions may be callable from other instructions or from itself, and/or may be invoked in response to detected events or interrupts. Computer-readable program instructions configured for execution on computing devices may be provided on a computer-readable storage medium, and/or as a digital download (and may be originally stored in a compressed or installable format that requires installation, decompression, or decryption prior to execution) that may then be stored on a computer-readable storage medium. Such computer-readable program instructions may be stored, partially or fully, on a memory device (e.g., a computer-readable storage medium) of the executing computing device, for execution by the computing device. The computer-readable program instructions may execute entirely on a user's computer (e.g., the executing computing device), partly on the user's computer, as a stand-alone software package, partly on the user's computer and partly on a remote computer or entirely on the remote computer or server. In the latter scenario, the remote computer may be connected to or in communication with the user's computer through any type of network, including a local area network (“LAN”) or a wide area network (“WAN”), or the connection may be made to an external computer (for example, through the Internet using an Internet Service Provider). In various embodiments, electronic circuitry including, for example, programmable logic circuitry, field-programmable gate arrays (“FPGA”), or programmable logic arrays (“PLA”) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart(s) and/or block diagram(s) block or blocks.

The computer-readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks. For example, the instructions may initially be carried on a magnetic disk or solid-state drive of a remote computer. The remote computer may load the instructions and/or modules into its dynamic memory and send the instructions over a telephone, cable, or optical line using a modem. A modem local to a server computing system may receive the data on the telephone/cable/optical line and use a converter device including the appropriate circuitry to place the data on a bus. The bus may carry the data to a memory, from which a processor may retrieve and execute the instructions. The instructions received by the memory may optionally be stored on a storage device (e.g., a solid-state drive) either before or after execution by the computer processor.

The flowcharts and block diagrams in the Figures illustrate the architecture, functionality, and operation of possible implementations of systems, methods, and computer program products according to various embodiments of the present disclosure. In this regard, each block in the flowchart or block diagrams may represent a service, module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. In addition, certain blocks may be omitted or optional in various implementations. The methods and processes described herein are also not limited to any particular sequence, and the blocks or states relating thereto can be performed in other sequences that are appropriate.

It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions. For example, any of the processes, methods, algorithms, elements, blocks, applications, or other functionality (or portions of functionality) described in the preceding sections may be embodied in, and/or fully or partially automated via, electronic hardware such application-specific processors (e.g., application-specific integrated circuits (ASICs)), programmable processors (e.g., field programmable gate arrays (FPGAs)), application-specific circuitry, and/or the like (any of which may also combine custom hard-wired logic, logic circuits, ASICs, FPGAs, and/or the like. With custom programming/execution of software instructions to accomplish the techniques).

Any of the above-mentioned processors, and/or devices incorporating any of the above-mentioned processors, may be referred to herein as, for example, “computers,” “computer devices,” “computing devices,” “hardware computing devices,” “hardware processors,” “processing units,” and/or the like. Computing devices of the above-embodiments may generally (but not necessarily) be controlled and/or coordinated by operating system software, such as Mac OS, iOS, Android, Chrome OS, Windows OS (e.g., Windows XP, Windows Vista, Windows 7, Windows 8, Windows 10, Windows 11, Windows Server, and/or the like), Windows CE, Unix, Linux, SunOS, Solaris, Blackberry OS, VxWorks, or other suitable operating systems. In other embodiments, the computing devices may be controlled by a proprietary operating system. Conventional operating systems control and schedule computer processes for execution, perform memory management, provide file system, networking, I/O services, and provide a user interface functionality, such as a graphical user interface (“GUI”), among other things.

For example, FIG. 17 shows a block diagram that illustrates a computer system 1700 upon which various implementations and/or aspects (e.g., .g., one or more aspects of the evaluation computing system 102, external system 150, user devices 120, other aspects of the operating environment 100, and/or the like) may be implemented. Computer system 1700 includes a bus or other communication mechanism for communicating information, and a hardware processor, or multiple processors, coupled with bus for processing information. Hardware processor(s) may be, for example, one or more general purpose microprocessors.

Computer system 1700 also includes a main memory, such as a random-access memory (RAM), cache and/or other dynamic storage devices, coupled to bus for storing information and instructions to be executed by processor. Main memory also may be used for storing temporary variables or other intermediate information during execution of instructions to be executed by processor. Such instructions, when stored in storage media accessible to processor, render computer system 1700 into a special-purpose machine that is customized to perform the operations specified in the instructions. The main memory may, for example, include instructions to implement the cooling features of any of the implementations above, such as the variable fan speed, and/or other aspects of functionality of the present disclosure, according to various implementations.

Computer system 1700 further includes a read only memory (ROM) or other static storage device coupled to bus for storing static information and instructions for processor. A storage device, such as a magnetic disk, optical disk, or USB thumb drive (Flash drive), and/or the like, is provided and coupled to bus for storing information and instructions.

Computer system 1700 may be coupled via bus to a display, such as a cathode ray tube (CRT) or LCD display (or touch screen), for displaying information to a computer user. An input device, including alphanumeric and other keys, is coupled to bus for communicating information and command selections to processor. Another type of user input device is cursor control, such as a mouse, a trackball, or cursor direction keys for communicating direction information and command selections to processor and for controlling cursor movement on display. This input device typically has two degrees of freedom in two axes, a first axis (e.g., x) and a second axis (e.g., y), that allows the device to specify positions in a plane. In some embodiments, the same direction information and command selections as cursor control may be implemented via receiving touches on a touch screen without a cursor.

Computing system 1700 may include a user interface module to implement a GUI that may be stored in a mass storage device as computer executable program instructions that are executed by the computing device(s). Computer system 1700 may further, as described below, implement the techniques described herein using customized hard-wired logic, one or more ASICs or FPGAs, firmware and/or program logic which in combination with the computer system causes or programs computer system 1700 to be a special-purpose machine. According to one embodiment, the techniques herein are performed by computer system 1700 in response to processor(s) executing one or more sequences of one or more computer-readable program instructions contained in main memory. Such instructions may be read into main memory from another storage medium, such as storage device. Execution of the sequences of instructions contained in main memory causes processor(s) to perform the process steps described herein. In alternative embodiments, hard-wired circuitry may be used in place of or in combination with software instructions.

Various forms of computer-readable storage media may be involved in carrying one or more sequences of one or more computer-readable program instructions to processor for execution. For example, the instructions may initially be carried on a magnetic disk or solid-state drive of a remote computer. The remote computer can load the instructions into its dynamic memory and send the instructions over a telephone line using a modem. A modem local to computer system 1700 can receive the data on the telephone line and use an infra-red transmitter to convert the data to an infra-red signal. An infra-red detector can receive the data carried in the infra-red signal and appropriate circuitry can place the data on bus. Bus carries the data to main memory, from which processor retrieves and executes the instructions. The instructions received by main memory may optionally be stored on storage device either before or after execution by processor.

Computer system 1700 also includes a communication interface coupled to bus. Communication interface provides a two-way data communication coupling to a network link that is connected to a local network. For example, communication interface may be an integrated services digital network (ISDN) card, cable modem, satellite modem, or a modem to provide a data communication connection to a corresponding type of telephone line. As another example, communication interface may be a local area network (LAN) card to provide a data communication connection to a compatible LAN (or WAN component to communicated with a WAN). Wireless links may also be implemented. In any such implementation, communication interface sends and receives electrical, electromagnetic, or optical signals that carry digital data streams representing various types of information.

Network link typically provides data communication through one or more networks to other data devices. For example, network link may provide a connection through local network to a host computer or to data equipment operated by an Internet Service Provider (ISP). ISP in turn provides data communication services through the worldwide packet data communication network now commonly referred to as the “Internet”. Local network and Internet both use electrical, electromagnetic, or optical signals that carry digital data streams. The signals through the various networks and the signals on network link and through communication interface, which carry the digital data to and from computer system 1700 are example forms of transmission media.

Computer system 1700 can send messages and receive data, including program code, through the network(s), network link and communication interface. In the Internet example, a server might transmit a requested code for an application program through Internet, ISP, local network and communication interface.

The received code may be executed by processor as it is received, and/or stored in storage device, or other non-volatile storage for later execution.

As described above, in various implementations certain functionality may be accessible by a user through a web-based viewer (such as a web browser), or other suitable software program. In such implementations, the user interface may be generated by a server computing system and transmitted to a web browser of the user (e.g., running on the user's computing system). Alternatively, data (e.g., user interface data) necessary for generating the user interface may be provided by the server computing system to the browser, where the user interface may be generated (e.g., the user interface data may be executed by a browser accessing a web service and may be configured to render the user interfaces based on the user interface data). The user may then interact with the user interface through the web-browser. User interfaces of certain implementations may be accessible through one or more dedicated software applications. In certain embodiments, one or more of the computing devices and/or systems of the disclosure may include mobile computing devices, and user interfaces may be accessible through such mobile computing devices (for example, smartphones and/or tablets).

Many variations and modifications may be made to the above-described embodiments, the elements of which are to be understood as being among other acceptable examples. All such modifications and variations are intended to be included herein within the scope of this disclosure. The foregoing description details certain embodiments. It will be appreciated, however, that no matter how detailed the foregoing appears in text, the systems and methods can be practiced in many ways. As is also stated above, it should be noted that the use of particular terminology when describing certain features or aspects of the systems and methods should not be taken to imply that the terminology is being re-defined herein to be restricted to including any specific characteristics of the features or aspects of the systems and methods with which that terminology is associated.

Conditional language, such as, among others, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

The term “substantially” when used in conjunction with the term “real-time” forms a phrase that will be readily understood by a person of ordinary skill in the art. For example, it is readily understood that such language will include speeds in which no or little delay or waiting is discernible, or where such delay is sufficiently short so as not to be disruptive, irritating, or otherwise vexing to a user.

Conjunctive language such as the phrase “at least one of X, Y, and Z,” or “at least one of X, Y, or Z,” unless specifically stated otherwise, is to be understood with the context as used in general to convey that an item, term, and/or the like may be either X, Y, or Z, or a combination thereof. For example, the term “or” is used in its inclusive sense (and not in its exclusive sense) so that when used, for example, to connect a list of elements, the term “or” means one, some, or all of the elements in the list. Thus, such conjunctive language is not generally intended to imply that certain embodiments require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general-purpose computer comprising one or more processors should not be interpreted as excluding other computer components, and may possibly include such components as memory, input/output devices, and/or network interfaces, among others.

While the above detailed description has shown, described, and pointed out novel features as applied to various embodiments, it may be understood that various omissions, substitutions, and changes in the form and details of the devices or processes illustrated may be made without departing from the spirit of the disclosure. As may be recognized, certain embodiments of the inventions described herein may be embodied within a form that does not provide all of the features and benefits set forth herein, as some features may be used or practiced separately from others. The scope of certain inventions disclosed herein is indicated by the appended claims rather than by the foregoing description. All changes which come within the meaning and range of equivalency of the claims are to be embraced within their scope.

### Example Clauses

Examples of implementations of the present disclosure can be described in view of the following example clauses. The features recited in the below example implementations can be combined with additional features disclosed herein. Furthermore, additional inventive combinations of features are disclosed herein, which are not specifically recited in the below example implementations, and which do not include the same features as the specific implementations below. For sake of brevity, the below example implementations do not identify every inventive aspect of this disclosure. The below example implementations are not intended to identify key features or essential features of any subject matter described herein. Any of the example clauses below, or any features of the example clauses, can be combined with any one or more other example clauses, or features of the example clauses or other features of the present disclosure.

Clause 1: A computer-implemented method, performed by a computing system having one or more hardware computer processors and one or more computer-readable storage devices storing software instructions executable by the computing system, the computer-implemented method comprising: accessing data associated with a plurality of objects; causing a graphical user interface to display the plurality of objects and information associated with one or more potential actions between two or more objects of the plurality of objects, wherein the one or more potential actions are associated with evaluator engine logic; receiving a first user input associated with the one or more potential actions; generating a first prompt for a first artificial intelligence (AI) model, the first prompt including the one or more potential actions, the evaluator engine logic, the accessed data, and first instructions, wherein the first instructions include instructions to generate an overview of the one or more potential actions based on the one or more potential actions, the evaluator engine logic, and the accessed data; providing the first prompt to the first AI model; receiving a first response from the first AI model, the first response comprising the overview of the one or more potential actions; causing the graphical user interface to display the overview of the one or more potential actions; generating a second prompt for a second AI model, the second prompt including a particular potential action of the one or more potential actions, the evaluator engine logic, the accessed data and second instructions, wherein the second instructions include instructions to generate a summary of the particular potential action based on the particular potential action, the evaluator engine logic, and the accessed data; providing the second prompt to the second AI model; receiving a second response from the second AI model, the second response comprising the summary of the particular potential action; and causing the graphical user interface to display an indication of the summary of the particular potential action.

Clause 2: The computer-implemented method of Clause 1, wherein generating the first prompt and generating the second prompt are triggered by the first user input.

Clause 3: The computer-implemented method of Clause 1 or 2, further comprising determining, by using an evaluator engine, the one or more potential actions between the two or more objects of the plurality of objects based on the accessed data, wherein the evaluator engine logic comprises output from the evaluator engine.

Clause 4: The computer-implemented method of any of Clauses 1-3, further comprising: receiving user input associated with the indication of the summary of the particular potential action; and causing the graphical user interface to display the summary of the particular potential action.

Clause 5: The computer-implemented method of any of Clauses 1-4, wherein the first AI model and the second AI model comprise a same AI model.

Clause 6: The computer-implemented method of any of Clauses 1-5, wherein the first AI model and/or the second AI model comprise at least one of: language models, or large language models (“LLM”).

Clause 7: The computer-implemented method of any of Clauses 1-6, wherein the data associated with the plurality of objects comprises at least one of: data received from one or more sensors; simulated data; or data retrieved from memory storage.

Clause 8: The computer-implemented method of any of Clauses 1-7, wherein the first instructions and the second instructions comprise instructions to generate output separately in two or more languages.

Clause 9: The computer-implemented method of any of Clauses 1-8, further comprising: receiving user preferences for displaying information on the graphical user interface, wherein the first instructions and the second instructions comprise instructions to configure output based on the user preferences.

Clause 10: The computer-implemented method of Clause 9, wherein the instruction to configure output based on the user preferences comprise instructions to create HyperText Markup Language (HTML) tags associated with information identified in the user preferences.

Clause 11: The computer-implemented method of Clause 10, wherein the instruction to configure output based on the user preferences further comprise instructions to embed the HTML tags into the output.

Clause 12: The computer-implemented method of any of Clauses 1-11, further comprising: receiving a third user input associated with the one or more potential actions, the third user input comprising a string of text; generating a third prompt for a third AI model, the third prompt including the string of text, the first response, and third instructions, the third instructions including instructions to generate an answer based on the string of text; providing the third prompt to the third AI model; receiving a third response from the third AI model, the third response comprising the answer; and causing the graphical user interface to display the answer.

Clause 13: The computer-implemented method of Clauses 12, further comprising causing the graphical user interface to display the string of text in association with the answer.

Clause 14: The computer-implemented method of any of Clauses 1-13, wherein the plurality of objects comprises one or more vehicles within a geographic area.

Clause 15: The computer-implemented method of Clause 14, wherein the data associated with the plurality of objects comprises at least one of: a position of the one or more vehicles; a bearing of the one or more vehicles; or capabilities of the one or more vehicles.

Clause 16: The computer-implemented method of any of Clauses 1-15, wherein the data associated with the plurality of objects comprises one or more reference tables with information connecting at least the two or more objects of the plurality of objects.

Clause 17: The computer-implemented method of any of Clauses 1-16, wherein the evaluator engine logic comprises connections between the two or more objects in association with a task.

Clause 18: The computer-implemented method of Clause 17, wherein the one or more potential actions comprise actions an object of the two or more objects can perform to accomplish the task based on the connections between the two or more objects.

Clause 19: A system comprising: one or more computer-readable storage mediums or devices comprising, configured to store, and/or storing program instructions; and one or more processors configured to execute the program instructions to cause the system to perform the computer-implemented method of any of Clauses 1-18.

Clause 20: One or more computer-readable storage mediums or devices comprising, configured to store, and/or storing program instructions, the program instructions executable by one or more processors to cause the one or more processors to perform the computer-implemented method of any of Clauses 1-18.

Clause 21: A computer-implemented method, performed by a computing system having one or more hardware computer processors and one or more computer-readable storage devices storing software instructions executable by the computing system, the computer-implemented method comprising: accessing information indicating one or more potential actions between two or more objects; determining, based on a similarity search on a set of rules and procedures, one or more logical blocks from the set of rules and procedures related to the one or more potential actions and/or the two or more objects; generating a first prompt for an artificial intelligence (AI) model, the first prompt including the one or more potential actions, the accessed information, the one or more logical blocks from the set of rules and procedures, and first instructions, the first instructions including instructions to generate indications of whether each of the one or more potential actions complies with the set of rules and procedures; providing the first prompt to the AI model; receiving a first response from the AI model, the first response comprising the indications of whether each of the one or more potential actions complies with the set of rules and procedures; and causing a graphical user interface to display the one or more potential actions and the indications of whether each of the one or more potential actions complies with the set of rules and procedures.

Clause 22: The computer-implemented method of Clause 21, wherein the AI model comprises at least one of: language models, or large language models (“LLM”).

Clause 23: The computer-implemented method of Clauses 21 or 22, wherein the similarity search comprises searching the set of rules and procedures for words or phrases associated with the one or more potential actions and/or the two or more objects.

Clause 24: The computer-implemented method of Clause 23, wherein determining the one or more logical blocks from the set of rules and procedures comprises: determining, based on the similarity search, one or more instances in the set of rules and procedures the words or phrases occurs; and for each of the one or more instances in the set of rules and procedures, determining a logical block comprising a portion of the set of rules and procedures in which an instance of the one or more instances occurs.

Clause 25: The computer-implemented method of Clause 24, wherein the portion of the set of rules and procedures comprises at least one of: a sentence in which the instance occurs; a page in which the instance occurs; a section in which the instance occurs; or a document of rules and procedures in which the instance occurs.

Clause 26: The computer-implemented method of any of Clauses 21-25, further comprising: causing the graphical user interface to display the two or more objects and information associated with the one or more potential actions; and prior to providing the first prompt to the AI model, receiving a user input requesting the one or more potential actions be checked for compliance with the set of rules and procedures.

Clause 27: The computer-implemented method of any of Clauses 21-26, further comprising: receiving a user input to the graphical user interface associated with a particular potential action of the one or more potential actions, the particular potential action associated with an indication that the particular potential action does not comply with the set of rules and procedures; sending the particular potential action to a user with authority to authorize the particular potential action; displaying the particular potential action to the user with authority on a separate graphical user interface; and receiving a second user input to the separate graphical user interface, the second user input comprising an authorization from the user with authority to perform the particular potential action.

Clause 28: The computer-implemented method of Clause 27, further comprising generating an alert based on the authorization.

Clause 29: The computer-implemented method of Clause 27, further comprising: determining, based on a second similarity search on the set of rules and procedures and the authorization, a second one or more logical blocks from the set of rules and procedures related to the one or more potential actions and/or the two or more objects; generating a second prompt for the AI model, the second prompt including the one or more potential actions, the accessed information, the authorization, the second one or more logical blocks from the set of rules and procedures, and second instructions, the second instructions including instructions to generate updated indications of whether each of the one or more potential actions complies with the set of rules and procedures; providing the second prompt to the AI model; receiving a second response from the AI model, the second response comprising the updated indications of whether each of the one or more potential actions complies with the set of rules and procedures; and causing the graphical user interface to display the one or more potential actions and the updated indications of whether each of the one or more potential actions complies with the set of rules and procedures.

Clause 30: The computer-implemented method of Clause 29, further comprising, prior to determining the second one or more logical blocks: accessing updated information associated with the two or more objects, the updated information including evaluator engine logic; and determining, by using the evaluator engine logic, an updated one or more potential actions between an updated two or more objects of the two or more objects based on the accessed information, wherein the one or more potential actions related to the second one or more logical blocks comprises the updated one or more potential actions and/or the two or more objects related to the second one or more logical blocks comprises the updated two or more objects.

Clause 31: The computer-implemented method of Clause 30, wherein the updated one or more potential actions comprises at least one potential action not in the one or more potential actions.

Clause 32: The computer-implemented method of Clause 30, wherein the updated information associated with the two or more objects comprises the authorization.

Clause 33: The computer-implemented method of any of Clauses 21-32, further comprising: recording the one or more potential actions, the accessed information, and the first response in a log; presenting at least a portion of the log to a user on a second separate graphical user interface; and receiving user input associated with the portion.

Clause 34: The computer-implemented method of Clause 33, wherein the user input associated with the portion comprises a verification of the first response.

Clause 35: The computer-implemented method of Clause 33, wherein the user input associated with the portion comprises a correction to the first response.

Clause 36: The computer-implemented method of Clause 35, further comprising: determining, based on a third similarity search on the set of rules and procedures and the correction to the first response, a third one or more logical blocks from the set of rules and procedures related to the one or more potential actions and/or the two or more objects; generating a third prompt for the AI model, the third prompt including the one or more potential actions, the accessed information, the correction to the first response, the third one or more logical blocks from the set of rules and procedures, and third instructions, the third instructions including instructions to generate updated indications of whether each of the one or more potential actions complies with the set of rules and procedures; providing the third prompt to the AI model; receiving a third response from the AI model, the third response comprising the updated indications of whether each of the one or more potential actions complies with the set of rules and procedures; and causing the graphical user interface to display the one or more potential actions and the updated indications of whether each of the one or more potential actions complies with the set of rules and procedures.

Clause 37: The computer-implemented method of any of Clauses 21-36, further comprising: receiving user input comprising a text string of text regarding the set of rules and procedures; determining, based on a second similarity search on the set of rules and procedures and the user input, a fourth one or more logical blocks from the set of rules and procedures related to the user input; generating a fourth prompt for the AI model, the fourth prompt including the fourth one or more logical blocks from the set of rules and procedures, the user input, and fourth instructions, the fourth instructions including instructions to generate an answer based on the string of text; receiving a fourth response from the AI model, the fourth response comprising the answer; and causing the graphical user interface to display the answer.

Clause 38: The computer-implemented method of any of Clauses 21-37, further comprising: accessing data associated with a two or more of objects; and determining, by using an evaluator engine, the one or more potential actions between the two or more objects of the two or more objects based on the accessed data, wherein the first prompt further includes logic received from the evaluator engine.

Clause 39: A system comprising: one or more computer-readable storage mediums or devices comprising, configured to store, and/or storing program instructions; and one or more processors configured to execute the program instructions to cause the system to perform the computer-implemented method of any of Clauses 21-38.

Clause 40: One or more computer-readable storage mediums or devices comprising, configured to store, and/or storing program instructions, the program instructions executable by one or more processors to cause the one or more processors to perform the computer-implemented method of any of Clauses 21-38.

What is claimed is:

1. A computer-implemented method, performed by a computing system having one or more hardware computer processors and one or more computer-readable storage devices storing software instructions executable by the computing system, the computer-implemented method comprising:
accessing data associated with a plurality of objects;
causing a graphical user interface to display the plurality of objects and information associated with one or more potential actions between two or more objects of the plurality of objects, wherein the one or more potential actions are associated with evaluator engine logic;
receiving a first user input associated with the one or more potential actions;
generating a first prompt for a first artificial intelligence (AI) model, the first prompt including the one or more potential actions, the evaluator engine logic, the accessed data, and first instructions, wherein the first instructions include instructions to generate an overview of the one or more potential actions based on the one or more potential actions, the evaluator engine logic, and the accessed data;
providing the first prompt to the first AI model;
receiving a first response from the first AI model, the first response comprising the overview of the one or more potential actions;
causing the graphical user interface to display the overview of the one or more potential actions;
generating a second prompt for a second AI model, the second prompt including a particular potential action of the one or more potential actions, the evaluator engine logic, the accessed data and second instructions, wherein the second instructions include instructions to generate a summary of the particular potential action based on the particular potential action, the evaluator engine logic, and the accessed data;
providing the second prompt to the second AI model;
receiving a second response from the second AI model, the second response comprising the summary of the particular potential action; and
causing the graphical user interface to display an indication of the summary of the particular potential action.

2. The computer-implemented method of claim 1, wherein generating the first prompt and generating the second prompt are triggered by the first user input.

3. The computer-implemented method of claim 2, further comprising determining, by using an evaluator engine, the one or more potential actions between the two or more objects of the plurality of objects based on the accessed data, wherein the evaluator engine logic comprises output from the evaluator engine.

4. The computer-implemented method of claim 3, further comprising:
receiving user input associated with the indication of the summary of the particular potential action; and
causing the graphical user interface to display the summary of the particular potential action.

5. The computer-implemented method of claim 4, wherein the first AI model and the second AI model comprise a same AI model.

6. The computer-implemented method of claim 5, wherein the first AI model and/or the second AI model comprise at least one of: language models, or large language models (“LLM”).

7. The computer-implemented method of claim 6, wherein the data associated with the plurality of objects comprises at least one of:
data received from one or more sensors;
simulated data; or
data retrieved from memory storage.

8. The computer-implemented method of claim 7, wherein the first instructions and the second instructions comprise instructions to generate output separately in two or more languages.

9. The computer-implemented method of claim 8, further comprising:
receiving user preferences for displaying information on the graphical user interface,
wherein the first instructions and the second instructions comprise instructions to configure output based on the user preferences.

10. The computer-implemented method of claim 9, wherein the instruction to configure output based on the user preferences comprise instructions to create HyperText Markup Language (HTML) tags associated with information identified in the user preferences.

11. The computer-implemented method of claim 10, wherein the instruction to configure output based on the user preferences further comprise instructions to embed the HTML tags into the output.

12. The computer-implemented method of claim 11, further comprising:
receiving a third user input associated with the one or more potential actions, the third user input comprising a string of text;
generating a third prompt for a third AI model, the third prompt including the string of text, the first response, and third instructions, the third instructions including instructions to generate an answer based on the string of text;
providing the third prompt to the third AI model;
receiving a third response from the third AI model, the third response comprising the answer; and
causing the graphical user interface to display the answer.

13. The computer-implemented method of claims 12, further comprising causing the graphical user interface to display the string of text in association with the answer.

14. The computer-implemented method of claim 13, wherein the plurality of objects comprises one or more vehicles within a geographic area.

15. The computer-implemented method of claim 14, wherein the data associated with the plurality of objects comprises at least one of:
a position of the one or more vehicles;
a bearing of the one or more vehicles; or
capabilities of the one or more vehicles.

16. The computer-implemented method of claim 15, wherein the data associated with the plurality of objects comprises one or more reference tables with information connecting at least the two or more objects of the plurality of objects.

17. The computer-implemented method of claim 16, wherein the evaluator engine logic comprises connections between the two or more objects in association with a task.

18. The computer-implemented method of claim 17, wherein the one or more potential actions comprise actions an object of the two or more objects can perform to accomplish the task based on the connections between the two or more objects.

19. A system comprising:
one or more computer-readable storage mediums or devices comprising, configured to store, and/or storing program instructions; and
one or more processors configured to execute the program instructions to cause the system to perform the computer-implemented method of claim 1.

20. One or more computer-readable storage mediums or devices comprising, configured to store, and/or storing program instructions, the program instructions executable by one or more processors to cause the one or more processors to perform the computer-implemented method of claim 1.
